(19) United States
(12) Patent Application Publication
(10) Pub. No.: US 2010/0217549 A1
(43) Pub. Date: Aug. 26, 2010

(54) System and method for fractional smart metering

(76) Inventors: Brian R. Galvin, Seabeck, WA (US); Jason Crabtree, Kingston, WA (US)

Correspondence Address: Brian R. Galvin, P.O. BOX 2360, SILVERDALE, WA, 98383-2360, US

(21) Appl. No.: 12/459,990

(22) Filed: Jul. 10, 2009

Related U.S. Application Data
(63) Continuation-in-part of application No. 12/383,993, filed on Mar. 30, 2009.
(60) Provisional application No. 61/208,770, filed on Feb. 26, 2009.

(51) Int. Cl. G06F 19/00; G01R 21/00

(52) U.S. Cl. 702/62

(57) ABSTRACT

A fractional smart metering system, comprising a processor coupled to a packet data network and a server software module executing on the processor and coupled to an operational database containing at least energy usage information pertaining to an energy consumer and obtained from meter readings at the consumer's premises, wherein the server software module is adapted to receive information over the network from a plurality of client software modules associated with energy resources further associated with the energy consumer, and wherein the server software module computes a measure of energy usage for a specific time interval for the consumer, said measure being determined at least in part based on a comparison between the information received from the client software modules associated with the consumer and the corresponding usage information obtained from the operational database, is disclosed.

### CROSS-REFERENCE TO RELATED APPLICATIONS

This application is a continuation-in-part of patent application Ser. No. 12/______, titled “Overlay Packet Data Network For Managing Energy And Method For Using Same”, filed on Jul. 7, 2009, which claims priority to Provisional Application Ser. No. 61/208,770, filed on Feb. 26, 2009, and is a continuation-in-part of patent application Ser. No. 12/383,993, titled “System and Method for Managing Energy”, filed on Mar. 30, 2009, the specifications of all of which are hereby incorporated in their entirety by reference.

### BACKGROUND OF THE INVENTION

1. Field of the Invention

The present invention is in the field of energy management, and in particular in the subfield of smart grid systems. Yet more particularly, the present invention pertains to systems for measuring energy usage by energy consumers.

2. Discussion of the State of the Art

While a robust electric power grid is widely recognized as a vital infrastructure component of a developed economy, technological progress in the field of electricity grid systems has not kept up with the pace of other important technological fields such as telecommunications. Most of the electric grid infrastructure has been in place for decades, and the basic architecture conceived by Thomas Edison and enhanced by the likes of George Westinghouse and Samuel Insull still prevails. Additionally, the current regulatory scheme in the United States discourages large-scale investment in transmission and distribution infrastructure, with the unfortunate result that the grid is often running near capacity.

A number of techniques have been devised to assist in maintaining grid stability during times of high stress, which normally means peak usage hours but also includes periods during normal usage when part of the grid goes offline, thus reducing the effective capacity of the grid or a region of it. It is commonplace for “peaking generators”, often operated by independent power producers, to be placed online at peak periods to give the grid greater capacity; since periods of high demand tend to lead to high wholesale power prices, the business model of peaking generator operators is premised on operating their generators only when the price that can be obtained is high. Large utilities, desiring to avoid the use of high-priced peaking generators when possible, also routinely participate in demand response programs. In these programs, arrangements are made by independent third parties with large commercial, industrial, or institutional users of power to give control to the third parties over certain electric loads belonging to large users. These third parties make complementary arrangements with electric utilities to provide “negative load” during peak periods, on demand, by shedding some portion of the loads under their control when requested by the utility. Typically the cost to the utility of paying these aggregators of “negawatts” (negative megawatts, or negative load available on demand) is much less than the corresponding costs the utilities pay to peak generators for actual megawatts. That is, the utilities pay for “dispatchable load reduction” instead of for “dispatchable peak generation”, and they do so at a lower rate. This arrangement is attractive to the utilities not only because of the immediate price arbitrage opportunity it presents, but also because, by implementing demand reduction, the utilities are often able to defer expensive capital improvements which might otherwise be necessary to increase the capacity of the grid.

A problem with the current state of the art in demand reduction is that it is only practical, in the art, to incorporate very large users in demand reduction programs. Large commercial and industrial users of electricity tend to use far more power on a per-user basis than small commercial and residential users, so they have both the motive (large savings) and the means (experienced facilities management) to take advantage of the financial rewards offered by participation in demand management programs. Additionally, large users of electricity already are accustomed to paying a price for power that depends on market conditions and varies throughout the day, and they often have already invested in advanced building automation systems to help reduce the cost of electricity by conserving.

Unfortunately, a large portion (roughly 33%) of the electric power used during peak periods goes to small users, who do not normally participate in demand management. These users often are unaware of their energy usage habits, and they rarely pay for electricity at varying rates. Rather, they pay a price per unit of electricity used that is tightly regulated and fixed. Partly this is due to the fact that the large majority of small businesses and homes do not have “smart meters”; the amount of power used by these consumers of electricity is measured only once per month and thus there is no way to charge an interval price (typically pricing is set at intervals of 15 minutes when interval pricing is in effect) that varies based on market conditions. Furthermore, the loads in the homes and businesses of small electricity users are invisible to the utilities; it is generally not possible for utilities to “see”, much less to control, loads in homes and small businesses. Loads here refers to anything that uses electricity, including but not limited to lighting, heating ventilation and air conditioning (HVAC), hot water, “white goods” (large appliances such as washers, driers, refrigerators and the like), hot tubs, computers, and so forth.

One approach in the art to improving the situation with small users is to install smart meters at homes small businesses. While the primary motivation for doing so is to enable interval-based usage measurement and the communication of interval-based prices to the users, it is also possible to provide the consumer with much more information on how she uses energy than was possible without a smart meter. Given this granular usage information, utilities and some third parties also hope to be able to send signals, either via pricing or “code red” messages (which ask consumers to turn off unnecessary loads due to grid constraints), or both. In some cases, third parties seek to provide visibility and control to utilities so that, when consumers allow it, the utilities can turn loads off during peak demand to manage the peak. A related method involves the use of “gateway” devices to access a consumer's (again, referring to residences, businesses, and institutions) home area networks (HAN) to communicate with or turn off local devices.

It is a disadvantage of the techniques known in the art that the consumers and small businesses are not, in general, provided with any substantial financial incentives to participate in demand reduction programs (other than merely by saving because they use less power). The “virtual power provider” generally sells “megawatts” as previously described by aggregating demand response capability of many small users and selling demand response services to the utility. This method similarly discourages consumer participation, because the majority of the financial rewards associated with the demand response are not generally passed along to the consumer. The companies that aggregate demand typically charge utilities for the peak reduction, but the consumer is unable to sell their available “megawatts” directly to a utility. This is problematic because this methodology reduces consumer incentives to participate in demand side management, which is a necessary component of modem grid management. And adoption is hampered by the general lack of willingness on the part of consumers to allow utilities to control significant portions of their electricity usage with the consumer having little “say” in the matter. And, from the utilities' point of view, the large variations in consumer usage patterns means that it is much harder for utilities to gage how much demand reduction is enough, in advance; compared to large, stable users such as large office buildings or industrial facilities, utilities face a complex mix of user patterns that are difficult to predict and virtually impossible to control. As a result, at the present time almost no demand reduction takes place among consumers and small business users of the electric grid.

Another problem in the art today is the incorporation of distributed generation and storage systems, which are proliferating, into grid demand management systems. In many cases, consumers are unable to do more than to offset their own electric bills with generation units (such as microturbines powered by wind, or solar panels on a roof, or plug-in electric hybrid vehicles that could add energy to the grid when needed), because utilities have neither the means nor the motivation to pay them for the extra electricity they generate. Many states require utilities to buy excess power generated; but, without an ability to sell that generated power at a price that represents a more holistic view of its value that includes “embedded benefits” (i.e. at a rate that may consider, but is not limited to, the effect on enhancing local power quality, proximity to loads, type of power generated and the associated reduction in carbon and other negative externalities—like sulfur dioxide and nitrogen dioxide—and the reduced capital costs resulting from the reduction of required capital investments in infrastructure), most distributed power generation remains economically unfeasible, to the detriment of all parties. With the growing number of markets associated with trading negative externalities associated with electrical power generation (most prominently including carbon, but also nitrogen dioxide and sulfur dioxide), it is necessary to fully account for the value of such energy sources and storage options, and to ensure that double counting of environmental benefits that are related to the generation and distribution of the electricity itself is not conducted. Sulfur dioxide and nitrogen dioxide became regulated in the U.S. under the 1990 Clean Air Act Amendments, which established the EPA's Acid Rain Program to implement a cap-and-trade method to reduce harmful emissions from the electric power industry. Additionally, while storage units may allow users to avoid peak charges and to even the flow of locally generated power (for instance, by storing wind power during high wind conditions and returning it when the wind conditions are low), it is generally not possible for users to sell stored power to the grid operator at its true value for the same reasons.

An additional challenge associated with integrating distribute energy resources with the grid is the lack of a cost-effective means of aggregating distributed power generation into a form that can be traded in a manner similar to the large blocks of power that are bought and sold by more traditional commercial power plants like coal and nuclear. Complex industry rules discourage participation and even consolidators have been hesitant to enter the market given the high set up costs associated with communications, staffing, and industry monitoring. A mechanism is needed to enable equal participation of distributed energy generators (e.g. solar panels on the roof of a home) and traditional power generators in order to encourage the development of these resources.

An underlying difficulty that contributes to the problems already described is that consumers (commercial, industrial, institutional, or residential participants in energy markets) have no way to differentiate between one unit of energy and another in energy distribution systems, such as the electric grid, that are best viewed as “continuous-flow energy networks”. This type of network can be contrasted with “discrete- or packet-flow energy distribution networks” such as the coal distribution system. The global oil distribution network is a good example of a hybrid, or mixed, energy distribution network that uses both discrete-flow and continuous-flow techniques at various points in the network. With continuous-flow energy distribution networks such as the electric power distribution system (or grid) and the natural gas distribution system, the units of energy are indistinguishable physically, one from another, at the point of consumption. That is, a consumer cannot differentiate one kilowatt of electricity arriving at her home or business from another, and in general has no ability to differentiate between energy having desirable qualities (to her) such as renewability, low carbon footprint, derivation from local or at least domestic (as opposed to foreign) sources, and so forth. Since the physical properties of electricity or natural gas are essentially fixed and do not vary based on the source, the only attributes consumers can know are quantity and price. While in some cases utilities make available about information about the aggregate sources of their electricity, and while they may in some cases make a small number of “packages” available to consumers based on differing mixes of sources (for instance, “black, green and in between” menu choices based on percentage of renewable or low-carbon sources for each option, with prices varying accordingly), it is in general true that consumers have no information about the particular energy they are using at any given time, and no ability to make informed choices as energy consumers.

Today's energy distribution networks are “information-poor” and treat energy as a commodity that is only differentiated by price. What is needed is an “information-rich” energy distribution network.

One approach to addressing the “information-poor” nature of current distribution systems that provide energy to consumers (taken herein to mean residential, industrial, institutional, and commercial consumers of energy) is “smart metering”. Smart meters are a natural extension of the well-established electricity meters that today measure electricity usage at virtually all consumer locations. Under the older (pre-smart meter) system of measuring electricity usage, human meter readers would physically go at regular, long intervals (monthly or bimonthly, generally) and read a current value, typically in kilowatt-hours, of total energy consumption at that site since the meter last “rolled over” (passed its maximum reading and started over at zero). This new value would have the previous value subtracted from it to give the energy used in the period since the last meter reading. There are two main problems with the older meter system: first, meter readers are expensive; second, because readings can only practically be taken at long intervals, there is no way for utilities to measure usage specifically during particular time intervals such as a peak hour. Without the ability to make readings at frequent intervals (a common desired target is to have fifteen-minute readings), it is practically impossible for utilities to offer or impose demand-based pricing schemes, for instance where electricity prices are set higher during periods of peak demand. For very large consumers, utilities and the consumers have found common ground and the consumers have allowed sophisticated measurement systems to be put in place (or have done it themselves), and have switched to demand-based pricing; these large consumers typically have building automation and energy control systems that allow them to manage energy usage and to avoid excessive usage during peak periods. By switching to demand-based pricing, these consumers get a lower overall energy bill because prices during periods of low demand are typically much lower than the fixed prices used in non-demand-based pricing schemes (usually these prices are set as fixed tariffs and reflect an average of peak and low usage prices that would have been charged in demand-based pricing schemes).

While to some extent the problem of obtaining frequent usage readings has been solved for very large consumers, the situation is very different for residential and small commercial users, who collectively account for approximately 50% of electricity usage in the United States. A solution that is currently favored by the utility industry as a whole is to gradually shift the entire user base to “smart meters”, which are energy meters that are connected via a data network to the utility and are able to take readings at arbitrary time intervals under the control of the utility. Deployment of smart meters, among other things, makes it possible for utilities to implement demand-based pricing schedules for all consumers served by smart meters, which is extremely important for utilities and consumers alike (as demand-based pricing should help to control demand especially at peak periods). But the cost of deploying smart meters is quite high, typically reaching several hundred dollars per installed smart meter. With tens of millions of ratepayers in the United States alone, switching completely to smart meters will likely cost many billions of dollars, and it will take a considerable period of time.

Besides their high costs, smart meters suffer from another disadvantage, albeit one which would not trouble utilities themselves. Since smart meters are being deployed exclusively by utilities in the United States (since it has always been the responsibility of the utilities to install, maintain, and own usage meters), widespread deployment of smart meters will tend to lock in consumers with their local utility. This situation, which prevails today, is in sharp contrast to the situation in the telecommunications industry, where many consumers have a choice of carriers, even for local service. Smart meter deployment will reinforce utilities' stranglehold on their markets, which may not serve the best interests of consumers or the economy as a whole.

It is an object of the present invention to provide an alternative to utility-installed smart meters that enables interval-based pricing for at least a substantial fraction of the loads of each consumer without requiring utilities to make large capital investments in networking equipment and smart meters. Specifically, it is an object of the present invention to enable a consumer-installable fractional smart metering capability that delivers benefits to both consumers and utilities, and that is capable of being deployed far more rapidly and at lower cost, and that does not lock in consumers to their local utilities for all energy information needs.

### SUMMARY OF THE INVENTION

According to a preferred embodiment of the invention, a fractional smart metering system, comprising a processor coupled to a packet data network and a server software module executing on the processor and coupled to an operational database containing at least energy usage information pertaining to an energy consumer and obtained from meter readings at the consumer's premises, is disclosed. According to the invention, the server software module is adapted to receive information over the network from a plurality of client software modules associated with energy resources further associated with the energy consumer, and the server software module computes a measure of energy usage for a specific time interval for the consumer, said measure being determined at least in part based on a comparison between the information received from the client software modules associated with the consumer and the corresponding usage information obtained from the operational database.

According to another preferred embodiment of the invention, a method for measuring energy usage, comprising the steps of receiving information via a packet data network from client software modules associated with energy load devices or energy generating devices associated with an energy consumer, receiving information from an operational database pertaining to energy usage by the energy consumer and obtained from meter readings at the consumer's premises, and computing a measure of energy usage for a specific time interval for the consumer, said measure being determined at least in part based on a comparison between the information received from the client software modules associated with the consumer and the corresponding usage information obtained from the operational database, is disclosed.

### BRIEF DESCRIPTION OF THE DRAWING FIGURES

FIG. 1 (PRIOR ART) is a block diagram illustrating common elements of electric power distribution systems.

FIG. 2 is a block diagram of simple energy information nodes (or iNodes) according to an embodiment of the invention.

FIG. 3 is a block diagram of a home energy management network according to an embodiment of the invention.

FIG. 4 is a block diagram of a home energy network with an integrated smart meter according to an embodiment of the invention.

FIG. 5 is a block diagram of various means for users to interact with home energy networks according to the invention.

FIG. 6 is a block diagram of an embodiment of the invention in which device-level iNodes are directly connected to the Internet.

FIG. 7 is a block diagram of an embodiment of the invention in which home iNodes are connected to local iNodes such as neighborhood energy management systems.

FIG. 8 is a block diagram of a local iNode according to an embodiment of the invention.

FIG. 9 is a block diagram of a commercial building energy management system with an iNode according to an embodiment of the invention.

FIG. 10 is a block diagram of a digital energy exchange according to an embodiment of the invention.

FIG. 11 is a block diagram of a digital energy exchange system according to an embodiment of the invention.

FIG. 12 is a block diagram of a trading iNode according to an embodiment of the invention.

FIG. 13 is a diagram of a process for allowing consumers to express energy usage preferences, and to have those preferences carried out, according to an embodiment of the invention.

FIG. 14 is a block diagram of a fractional smart metering system according to an embodiment of the invention.

### DETAILED DESCRIPTION

The inventors provide, in a preferred embodiment of the invention, a system for managing continuous-flow energy distribution networks that is particularly adapted for managing electric power demand and distributed generation capacity among a large number of consumers, such as residential, small and large commercial, institutional (that is, hospitals, schools, and the like), and industrial users. The system relies on an overlay packet data network comprised of energy information nodes, or iNodes, which overcomes the previously discussed limitations BY overlaying a rich set of informational attributes on continuous energy flows such that consumers can use these information attributes and dimensions to make informed energy choices. A key advantage of the invention is that while a single physical network carries power from all sources, the available energy at ant given node is priced and allocated separately as a finite resource based on data attributes of the system.

Furthermore the new system enables consumer preferences to be implemented through selection of energy sources by explicitly named sources, or brands, or by any of a large number of information attributes or dimensions. The system of the invention enables new consumer behaviors such as paying more for certain energy source types, or even avoiding purchase (embargoing) of certain energy types or suppliers (for example, some consumers may choose to undertake the difficult path to becoming a “no coal electrical household (or business)” by refusing to take any coal-based electricity, no matter the cost (or even the lack of availability of alternatives for some periods). In addition, information attributes create a large opportunity for commercial branding, advertising, search and market making, in addition to passing on regulatory compliance information to consumers.

For the purposes of describing the invention, two related terms are used herein. An “eNode” is a physical node in a continuous flow energy distribution system at which energy is stored or transformed (in the sense that generation and consumption of electricity are both energy transformations, since energy is never created nor destroyed). Examples of eNodes include switches and breakers, generators, motors, electric appliances, home power distribution panels, meters, and so forth. The continuous flow electrical distribution network can be thought of as a network of “pipes” or “channels” connecting a large number of eNodes; electricity flows through these channels (mostly these are wires of course) and is transformed, stored, controlled, and measured at various eNodes. While the examples described herein will be electrical network examples, the same descriptions could be made by reference to other continuous flow energy distribution networks, or the continuous flow portions of mixed energy distribution networks, without any loss of generality; the invention should be understood to have as its scope any continuous flow energy distribution systems and the focus on electricity should be understood as being exemplary and not limiting.

A key element of the invention is the use of an overlay packet data network comprised of “iNodes” and coupled to the continuous flow energy distribution network of eNodes that was just described. In general, iNodes are associated with (or coextensive with) corresponding eNodes, and have interfaces capable of bidirectional data exchange with other iNodes. For example, where a metering device is placed in a physical network (this is an example of an eNode), an iNode would be a data device adapted to receive readings from the metering device and to pass those readings on, via a packet data network, to other iNodes. Conceptually, the entire physical, continuous flow, energy distribution network may be overlaid by a packet-based data network of iNodes that communicate sensor readings, perform calculations related to the energy flows in the energy network, send control signals to actuating elements in the physical network (such as a signal to open a breaker, or to start a generator), and communicate information pertaining to the energy network to interested users (both human and automated).

Although modularity of iNodes it is not necessary according to the invention, most iNodes described herein are highly modular in nature so they can be easily connected peer-to-peer and in trees or hierarchies and inserted into networks at different levels. Modular design has as advantages the facilitation of scalability, flexibility, security, robustness, standardization, and suitability for progressive deployment.

The use of a network of iNodes makes it possible to collect detailed data about usage patterns from large numbers of energy users, including how these usage patterns vary during various time periods, including peak demand periods and periods when sources of renewable energy (such as wind or solar) are unavailable or are available in abundance. Additionally, detailed data on how each user reacts (either automatically or otherwise) to management signals sent during peak demand or other periods, is collected. For example, some users may significantly reduce demand when requested, and may do so promptly. Other users, conversely, may not react at all, or may react sporadically. The same variations in response may occur among operators of distributed generation or storage facilities. There are many reasons why reactions will vary, and even why reactions may significantly deviate from demand reductions that were explicitly volunteered by a user. For example, when a peak period arrives, a user who volunteered to participate in demand reduction might be on vacation, or out of their home for any reason, and so many of the loads that would be targeted may already be secured (turned off). Similarly, some user-owned distributed generation facilities may be able to react to management signals by changing the generation profile, while others (for instance, solar systems) may not be able to change in response to demand management signals (because they are dependent on the sun or another uncontrolled factor).

According to an embodiment of the invention, this usage data is analyzed to create response profiles for each affected user. A response profile reflects an amount of load likely to be actually reduced (or generated) by a user, when requested. The profile may be quite complex, reflecting the varying predicted behaviors for a user on different days, at different times, during different seasons, and so forth. Response profiles can also be generated, according to the invention, on classes of users, large or small, who behave in similar ways; it is not necessary for each user to have an individual response profile. Furthermore, response profiles can be quite dynamic; for example, a response profile may express a conditional behavior such as “if there has been usage of at least X kwh in the two hours prior to the period of interest, then the user is likely at home and the expected response is Y; otherwise the expected response is Z”. In the example given, Z would likely (but not necessarily) be less than Y, and would reflect the fact that both fewer loads are likely to be active (because the user is away, as inferred by lack of use in the earlier period) and that no user reaction to any demand reduction request is possible because the user is likely not at home. In other embodiments of the invention, users may have home automation systems implemented and could receive notification via email, SMS text message or other means while away from home, and thus be enabled to take actions to reduce load when needed; this capability would be reflected in the response profile for such users or classes of users.

In an embodiment of the invention, consumers and small businesses participate voluntarily in supply (generation and storage) or demand (consumption) management programs by establishing preferences. Preferences can take many forms. In some cases, users may state that certain loads are “off limits” or “critical”, and can never be turned off remotely for any load conditions. Other loads may be given one or more attributes that can used to determine if the load is available in any given situation for remote deactivation. Attributes could include time of day, length of time since the load was turned on, length of time since the load was last remotely deactivated, level of criticality of the demand reduction effort, price to be paid for shedding the load (“don't take this load offline remotely unless I will be paid $1 for the sacrifice”), or even the communication required to confirm (for example, “this load can only be turned off if a message is sent to its automatic controller and the automatic controller states that it is safe to turn off the device”). Another user might express the preference that stored solar energy will be placed on the grid when the price is at a certain level, or when the level of criticality of the peak is sufficiently great. It will be appreciated that any number of consumer or small business preferences are possible for controlling when and whether one or more loads are made available for remote deactivation. Moreover, the same considerations that apply for deactivation can also be applied for activation in the case where generating capacity or storage capacity is available. Consumers and small businesses may have, in aggregate, substantial amounts of power in storage or ready to be generated on demand, if the management system was in place to request it and to manage it. Again, each user's supply-side resources (generation and storage capacity) can be made available according to preferences established by a user. Each response profile also reflects the geographic location of the user or class of users to whom it pertains. This information is important for determining which utility, and which particular grid locations (such as substations, tie lines, or regions) will be affected by the activation of the response profile, and to what extent.

In an embodiment of the invention, a number of response profiles are combined to create a response package. Because statistical behavior of users whose profiles are combined in the response package is known, and because a large number of profiles are normally combined into a package, it is possible according to the invention to estimate with good accuracy how much load reduction (or generation) each response package represents. For example, a response package made up of the collected response profiles of 10,000 consumers might be expected to yield 1.5 MWh (megawatt-hours) of load reduction during a particular 15-minute peak load period. Each time this response package is “invoked” (that is, each time a signal is sent to all the users represented by the response package), the actual demand change effected is measured, and used to refine the statistical model for each response profile and for the response package as a whole. In this way, according to the invention, the system for energy management continually adjusts to maintain highly accurate models of supply and demand changes in response to invocations of response packages (reductions through load shedding or additions through generation of power or release of power from storage). As with response profiles, each response package has a geographic element. For instance, it may represent elements (loads and generation/storage elements) spread across a particular utility's area of responsibility, or it may represent elements in a particular urban region.

In a preferred embodiment of the invention, response packages are made available for purchase by third parties. Purchasers could be utilities who desire to directly manage demand, or they could be aggregators who resell demand management to utilities at peak period. According to the invention, a given response package can be sold for any time period at any time in the future (or indeed for the current time period). Thus a response package for reducing load in San Francisco by 10 MWh for the 15-minute interval starting at noon on Friday, Mar. 31, 2010 could be sold at any time before 12:15 on that day. Because the package is sold, according to a preferred embodiment of the invention, on an open market, it is likely that the price would vary over time based on market participants' estimates of the likely demand for power at the critical time for this package (that is, at 12:00 on Mar. 31^{st}). In principle, the package can be sold more than once according to the invention, although in the end only one “owner” is able to actually elect to invoke the demand response action represented by the package. It should be noted that actual exercise of the demand response action represented by any given response package is necessary according to the invention; if load conditions are markedly different from what the final purchaser expected, that entity may elect not to incur additional costs (described below) by actually exercising the demand response action.

According to an embodiment of the invention, consumers make their preferences concerning their willingness to participate in on-demand energy management actions (that is, load reductions or provision of power from generators or storage systems) known in advance. Since consumers are unlikely to be willing to enter into long-term forward contracts for electric power actions that they may find quite unpalatable when a critical day arrives (for instance, if the weather is much warmer than expected, consumers may balk at letting their air conditioners be turned off), it is possible according to the invention for consumers to override their preferences at any time. Indeed this is one of the reasons that relying on consumers for demand response is so problematic, and why utilities seek to have remote control whenever possible (although this is rarely possible, and is even illegal in some jurisdictions because of regulatory requirements). In order to provide a level of control that consumers will want or require, and to provide a reasonable energy management capability to utilities, the combination of a number of consumers' (again, these can also be businesses) response profiles into response packages of sufficient size that they will be large enough to be useful and will have predictable statistical behavior, is carried out. According to a preferred embodiment, when a utility or other entity actually invokes a response package (for instance, by actually requesting the demand to be reduced by 10 MWh during the critical period), all of the end users that make up the response package are sent signals directing them to take the appropriate actions which they previously volunteered to take. While some will fail or refuse to do so, this has generally already been taken into account by building the response profiles and the response package to reflect the statistical patterns that this particular package of users has shown in the past, so according to the invention the actual demand response seen should closely approximate that specified as the “rating” of the response package (in the example above, the rating would be 10 MWh of demand reduction in the target time period).

Actual responses that occur when a response package is invoked are measured according to an embodiment of the invention. This measurement is used to refine statistical models used for response profiles, as described above. Also, according to an embodiment of the invention, an invoking entity (an entity which invoked a supply or demand response action associated with the response package) may optionally only be charged according to a supply or demand response that actually took place. For instance, while 10 MWh was forecasted and requested, if only 9.5 MWh was actually achieved, the price paid by an invoking entity would be reduced. Any reduction could be linear, so that in the example given the entity's actual price is reduced by 5%, or it could be set by any formula agreed in advance by the parties in the marketplace (for instance, the price difference could be set at 5% reduction for any shortfall from 0% to 5%, 10% for any shortfall above 5% but less than or equal to 10%, and so forth). It should be appreciated that any price adjustment schema can be used according to the invention, and that similar adjustments (or no adjustment) could be made if the response action exceeded what was requested (typically, one would expect that any overage would not be charged to an invoking entity, but this is not required according to the invention).

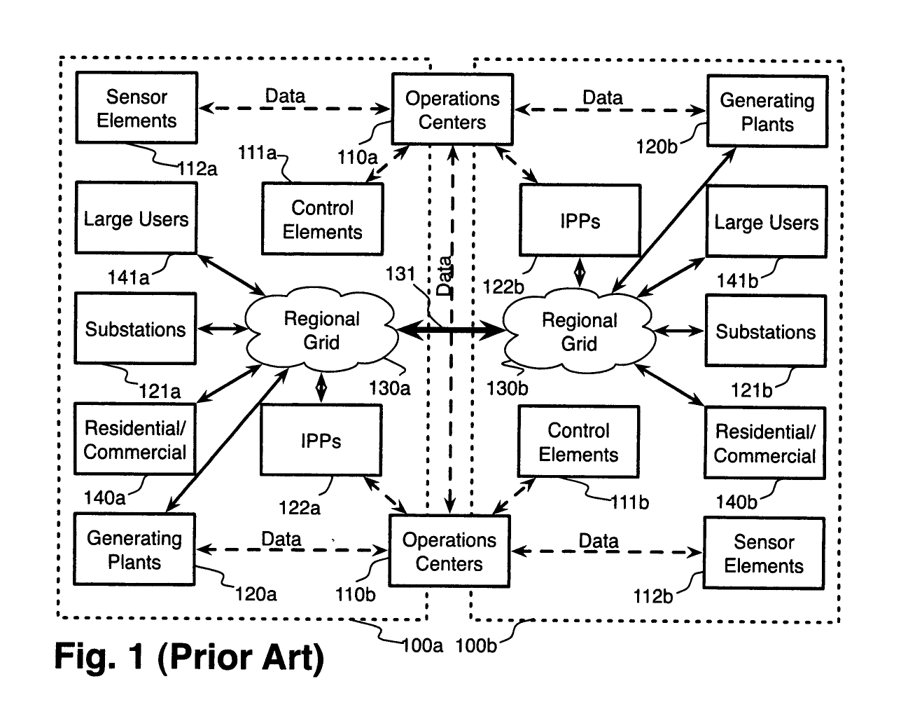

FIG. 1 illustrates many of the elements of continuous-flow electricity distribution networks as currently known in the art, and is provided to give some context to the embodiments illustrated in subsequent figures and described below. Electricity is generated in a large number of utility-owned generating plants 120 as well as many independent power producers 122 such as wind and solar farm operators, peaking load providers, and the like. The generated electricity is placed onto one or more regional distribution grids 130. Regional grids are often interconnected by high-voltage interconnects 131 so that electricity can flow relatively freely from where it is generated to where it is consumed. Power is delivered variously from regional grids via substations 121 (although substations 121 are not always used) to large users 141, residential and commercial users 140, and others. Grid operations are controlled from one or more operations centers 110, which rely on measurements from sensor elements 112 to measure grid operating parameters (such as voltage, frequency, phase, current, switch positions, device temperatures, and many others). Changes to grid operations, such as isolating faults, are carried out under control of operations centers 110 using one or more of a large number of control elements 111. In the art, and illustrated by dashed lines, operations centers are typically connected by specialized data links to control and sensor elements, and they also routinely share data between them. Several standard protocols, including SCADA and OASIS, are used for data communications between electric utilities, and within electric utilities to connect with devices. However, in the art there are no means established for data communications between utilities and most non-utility entities, with the exception of wholesale markets, independent power producers, and some large industrial and commercial energy users who have integrated to the utilities' communications protocols. Hence electrical distribution networks today are typified by very limited data connectivity, both in terms of device coverage (most electrical devices are not connected in any way) and in terms of participation by all potentially interested parties (the vast majority of entities that use electricity are completely disconnected from the grid in the sense of data, and have no visibility at all into real-time conditions, nor any ability to make meaningful decisions about their consumption of energy.

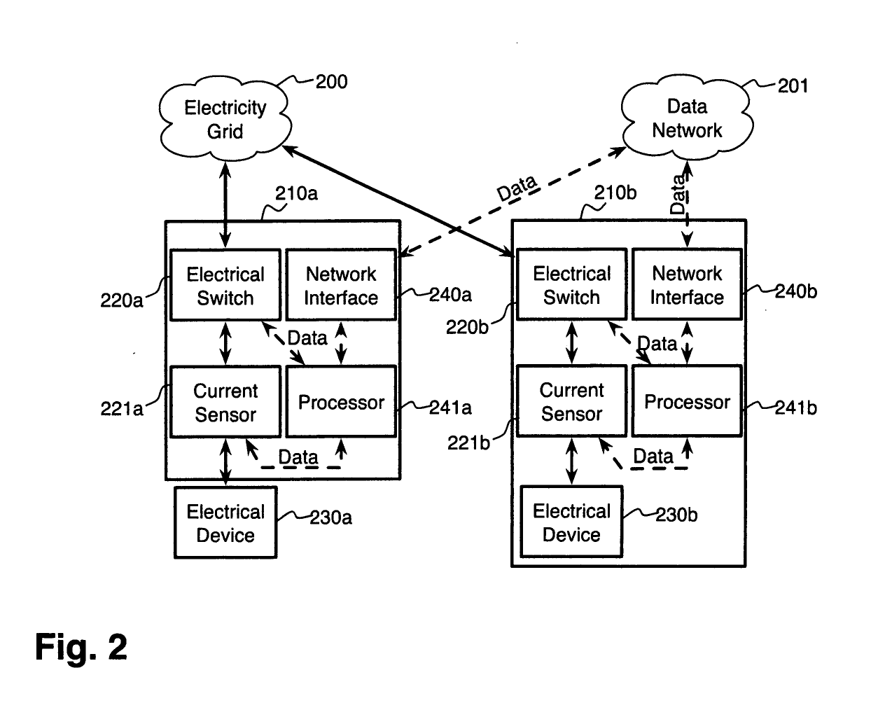

FIG. 2 illustrates two examples, according to a preferred embodiment of the invention, of device-level iNodes. iNodes 210a and 210b are each associated with a single electrical device 230a and 230b. Each electrical device is connected to the electricity grid 200 via an electrical switch 220 that interrupts flow when required, and optionally via a current sensor 221 which can measure real or reactive current (current sensors are well-known in the art). These components can optionally be provided, as shown in FIG. 2, as internal components of iNodes 210. In an embodiment of the invention, iNode 210a is a device which can plug in to a standard wall socket and pass electricity through electrical switch 220a and current sensor 221a to external electrical device 230a, which in some embodiments is plugged into female receptacles provided in the packaging of iNode 210a. It is not necessary that the iNode be configured for plugging in to wall sockets; in other embodiments iNode 210a is wired directly in to a facility's electric system. When hard-wired in to electrical power, iNode 210a may either also have hard-wired electrical connection out to electrical device 230a, or as before it may have standard electrical sockets for the connection of one or more electrical devices 230a. iNode 210b is an example of embodiments in which electrical device 230b is an integral part of an iNode; for example iNode 210b could be a smart appliance that is wired in the normal way to electrical grid 200 typically via household or building-level power distribution panels (not shown). iNode 210b essentially illustrates a smart device that is both an eNode and an iNode. In some embodiments, iNodes comprise only current sensor 221a or electrical switch 220a, rather than both. For example, an iNode might be designed to measure current through an eNode (electrical device 230) but not to interrupt power to it. For example if electrical device 230a is a generator with independent control circuitry, iNode 210a would be able to measure generated power from generator 230a and feed that data to data network 201.

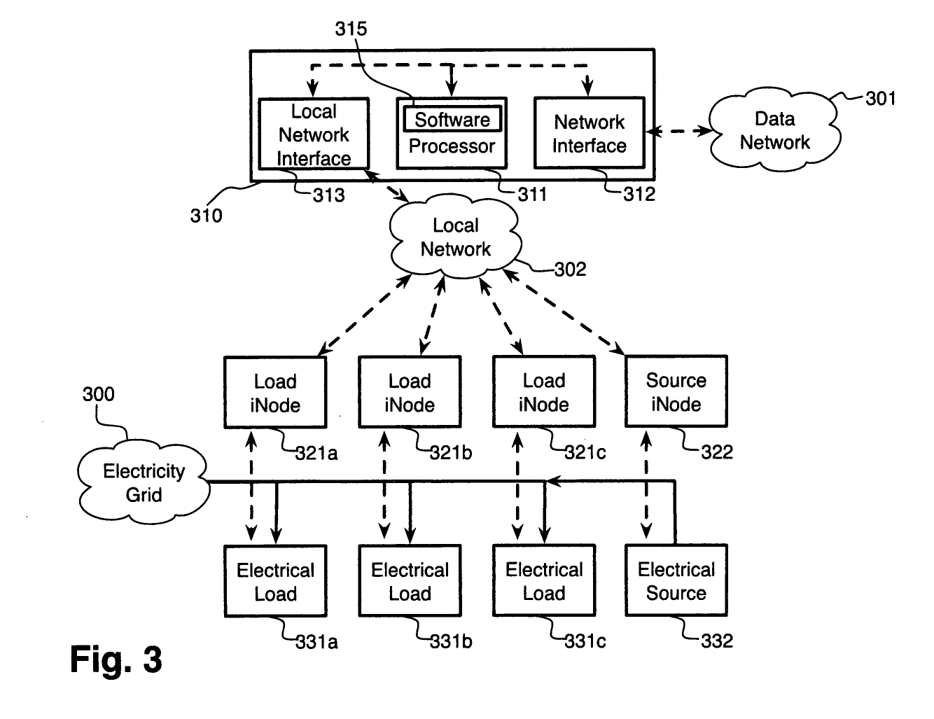

According to preferred embodiments, iNodes comprise at least a processor 241 such as a standard microprocessor or a customized processor (both very common in the art), and a network interface 240, which is connected to data network 201. Processor 241 is adapted either to receive input readings from current sensor 221 or electrical switch 220 (or both), or to send output signals to electrical switch 220, or to do both. In addition, in other embodiments iNodes can comprise voltage sensors, temperature sensors, voltage regulators (to receive output from processor 241), or any other sensing or actuating devices known in the art. iNodes are defined by the interoperation of one or more electrical sensors or actuators with a processor 241a that can communicate with other processors 241b by passing data through network interface 240a across data network 201 to another network interface 240b associated with the other processor 241b. Various embodiments showing different arrangements of iNodes to accomplish different purposes will be illustrated and described with reference to FIGS. 3-12; in all of them, and all other embodiments of the invention, it should be understood that any arbitrary sensor or actuator elements can be used in any given iNode, but all iNodes have at least a processor 241, a network interface 240, and at least one means of sensing or controlling eNodes (electrical devices 230).

Data communications between iNodes in any given embodiment can be accomplished using any data communications protocol known in the art (or indeed any novel proprietary protocol); the invention does not rely on, nor require, any particular data communications protocol. Common protocols that may be implemented in network interfaces 240 include transmission control protocol (TCP), universal datagram protocol (UDP), hypertext transfer protocol (HTTP), Java remote procedure calls (RPC), simple object access protocol (SOAP), and the like.

FIG. 3 illustrates a typical home or small business energy management system, according to an embodiment of the invention. Electrical power is sent from electricity grid 300 to electrical loads 331, again usually through a power distribution panel and often via a electricity usage meter (both not shown for simplicity). Electrical loads 331 can include any electrical devices that consumer electric power, such as heat pumps and air conditioners, lights or common lighting circuits, hot tubs, computers, ovens, ranges, refrigerators and other kitchen appliances, and any number of other electrical devices common in the art. One or more electrical loads 331 are coupled with load iNodes 321, for example of the type shown in FIG. 2 as iNodes 210. It is not necessary that every load 331 in a given home or small business has a coupled iNode 321; in many cases only some loads will be monitored or controlled by an iNode. Also, load iNodes 321 may vary among themselves in terms of the degree of coupling with their respective loads 331. Some may measure current only, others may measure current and voltage, while yet others may measure those plus frequency. Some may in fact measure nothing at all, but serve only as controllers. Similarly, some iNodes 321 will have no ability to control or interrupt electric power to its respective electrical load 331, while others will be able to interrupt load, and yet others will be able to modify the characteristics of the electric power or control the operation of the electrical load 331. Also, some iNodes 321 may be coupled to a plurality of electrical loads 331, while others may (as shown) only couple to one. In some embodiments, one or more electrical sources 332 are also present in a home or small business. Some examples of electrical sources common in the art include solar panels or arrays, wind turbines, or small internal combustion generators. Electrical sources or generators feed power into the home power system and, if it generates more electricity than is used in the home, they can actually cause electricity to flow back to electricity grid 300. Source iNode 322 is an iNode similar to those iNodes 210 described above, and is adapted to sense the power being generated by electrical source 332. In some embodiments source iNode 322 is also adapted to control, particularly by starting and stopping but potentially also by regulating output, electrical source 332. The various iNodes (321 and 322) are connected via local network 302 to gateway iNode 310. Local network 302 is commonly a simple home data network such as is provided through use of a wireless router connected to or embedded in a broadband modem (such as a cable or DSL modem). In other cases, local network 302 is a small business LAN. In a preferred embodiment, local network 302 is a wireless communications network formed using a specialized protocol such as Zigbee™ that is designed for low-power wireless data communications. Such networks are useful because it allows load iNodes 321 and source iNodes 322 to be equipped with inexpensive and low-power wireless communications capability, and therefore greatly assists in facilitating easy installation of iNodes since in most homes and small buildings any wired data network is usually separate from electrical power wiring networks. Low power is important in these wireless applications because it allows low-cost transmitters that have long battery life. In other embodiments, local network 302 is of a data-over-power-lines design, several of which are known in the art (for example, Lonworks™). These are less common and often more expensive than wireless networks, but they have the advantage of requiring only one wiring system and of avoiding some of the problems with wireless coverage that are common in buildings (and which sometimes require the installation of a number of wireless repeaters that receive and retransmit wireless signals to aid in their propagation throughout buildings). In other embodiments, local network 302 may be identical with external data network 301, as when each source iNode 322 and load iNode 321 is directly connected either to the Internet or to a neighborhood or building-wide (as where the group of iNodes shown in FIG. 3 belongs to a tenant in a commercial building or an apartment building) wireless data network. Gateway iNode 310 is so called because it acts as a gateway between local iNodes such as source iNode 322 and load iNodes 321. In some cases it also acts as a network gateway as is illustrated in FIG. 3, acting to bridge the local network 302 and external data network 301 such as the Internet (in cases where local iNodes are directly connected to external data network 301, this network gateway function would not exist, and gateway iNode 310 is optional depending on the information flow desired according to each embodiment).

Gateway iNode 310, in an embodiment of the invention, comprises a processor 311 and a local network interface 313, as well as a network interface 312 for coupling to external data network 301. In configuration where local iNodes connect directly to external data network 301, gateway iNode may only have one network interface 312. Gateway iNodes 310 at a minimum have an operating system operating on, and a storage medium (not shown) coupled to, processor 311; in all figures showing processors in iNodes, it is intended to be understood that some form of local storage and an operating system are understood to be included in the processor element; these are not shown to avoid undue complexity but are considered to be inherent to the functioning of any processor.

In various embodiments of the invention, software 315 executes on processor 311 to carry out the key logical functions of gateway iNode 310 as part of an overlay packet data network overlaid across some set of elements (331 and 332 in the embodiment illustrated in FIG. 3) of the electricity distribution network of electricity grid 300 and its connected elements (that is, an electricity distribution network as referred to herein refers to networks comprising one or more of the elements of FIG. 1 coupled by one or more electricity grids 130 (or 300). For example, in some embodiments software 315 receives (via local network interface 313) updates from local load iNodes 321 and source iNodes 322 concerning their state; example of such updates include current, voltage, frequency, true and reactive power readings, as well as settings of control elements such as switches. Updates may be sent from local iNodes on a regular basis, for example every 15 seconds, or when a value changes by some specified minimum amount, for example when changed by more than 10% from average of last five readings, or when polled by software 315. Software 315 in some embodiments sends control signals to control elements associated with local iNodes. For example, in response to a signal received from data network 301, software 315 could automatically shed some or most electrical loads under its control (that is, controlled by actuators or control elements in turn controlled by one of its child load iNodes 321a-c) by sending signals to the appropriate load iNodes instructing them to interrupt current to one or more of their controlled loads. Similarly, software 315 could, in response to a signal from data network 301 or at a scheduled time (determined from a schedule stored in its associated data storage), send a signal to source iNode 322 instructing it to start or to stop generating electricity, or to change the amount being produced. In these embodiments, gateway iNode 310 becomes a key element of a system that enables dispatched electricity supply or demand management, as it is adapted to be connected via data network 301 to one or more dispatchers, to process received signals in order to determine precisely what is to be done locally, and to carry out the requested actions by sending control signals to one or more child iNodes associated with it (generally in the same household, or tenant); it is also adapted for being a data collection element of a larger system by managing the collection of operating data from all of its child iNodes, processing that data as by aggregating it, and passing the data “upstream” via data network 301 to other system elements that may for example aggregate data from a large number of gateways 315.

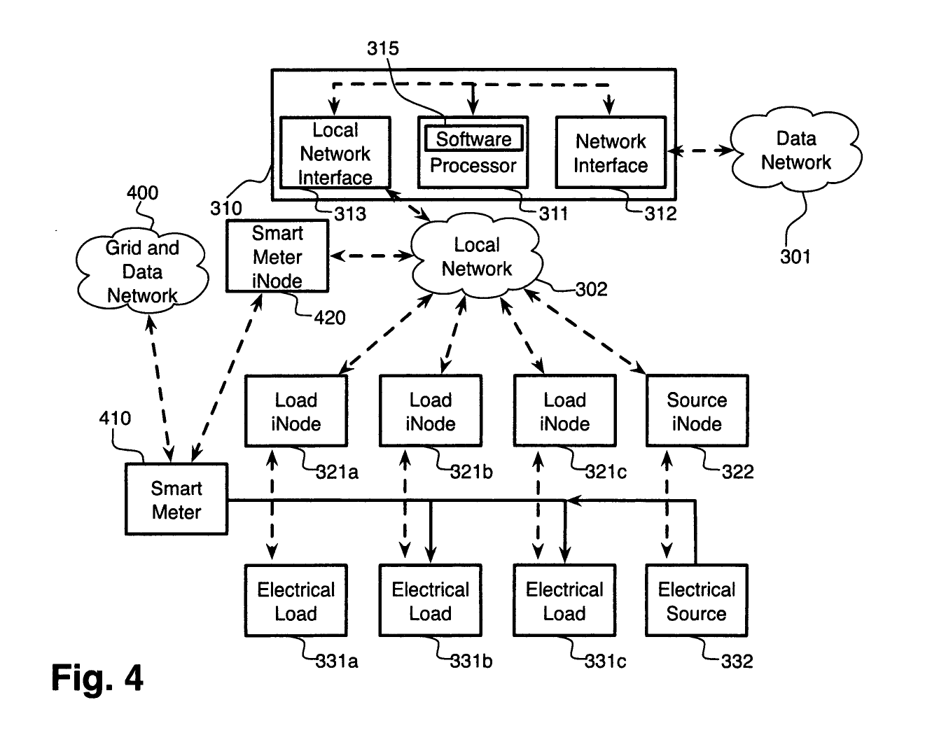

In another embodiment of the invention, and referring to FIG. 4, an energy management network for a home or small business similar to that of FIG. 3 is illustrated, with the addition of smart meter 410. Generally, all users of electricity who draw at least some of their power from electric grid 400 are provided (by the utility) with a meter for measuring the amount of energy used at a particular location. In the past, and still today in a large proportion of locations, meters are read by human meter readers on a monthly or semi-monthly basis. This presents obvious cost implications for utilities, which must pay those readers, and has led to many innovative approaches (including having consumers read their own meters with periodic unannounced audits by an external, utility-pair meter reader). Recently, a wave of introductions of automated meter reading (AMR) systems has been seen. These have quickly been succeeded by a more useful innovation, the smart meter 410, and its accompanying advanced metering infrastructure (AMI). While one of the goals of utilities in automating meter reading has been to reduce and eventually eliminate the need for human meter readers, another potentially much more lucrative motivation has been the possibility of obtaining meter readings on a frequent basis instead of only once per month. If meters are read, for example, every fifteen minutes, then utilities are able to measure how much energy is used by each ratepayer (consumer, whether commercial, residential, institutional, or industrial) during peak usage periods. This is an essential precondition to the very desirable (from the utilities' point of view) shift to variable pricing schemes. In a variable pricing scheme, the price of a unit of electricity (typically measured in kilowatt-hours, or kwh) is varied based on demand. During peak periods, the cost of generating electricity is commonly much higher, as expensive (and often independently operated by for-profit IPPs) peaking power plants must be utilized for a portion of the overall load; by contrast, during low-demand period most power is generated by very low-cost sources such as large coal plants and hydroelectric plants. Smart meters make all this possible, partly by being connected to the operations centers of utilities by a data network associated with the grid (shown together as grid and data network 400). In most cases, smart meters are designed to enable integration of home automation systems via local network 302. For example, small businesses or homes with wireless automation systems for managing lighting, HVAC (heating, ventilation, and air conditioning) systems, and the like are able to integrate these systems with smart meters. Often this is done to enable consumers to participate in optional (or even mandatory) demand response programs in which utilities are allowed to turn off, automatically, certain loads to reduce demand during peak periods (typically providing a discount to consumers willing to enter into such arrangements as an inducement to do so).

In an embodiment of the invention, smart meter 410 is integrated with a home energy management network according to the invention through smart meter iNode 420. Smart meter iNodes act in effect as a gateway to the smart meter and to the utility beyond. As such, it will typically have an internal architecture similar to that of gateway iNode 315, although this is not necessary as in some cases smart meter 410 can be integrated directly with local network 302, as when a Zigbee™-compliant smart meter is used with a Zigbee™ home energy management network. In some embodiments, smart meter iNode acts as a load iNode, passing meter readings to gateway iNode 315. Gateway iNode 315 is able, with the benefit of meter-level usage data (which provides data about total usage in the home or business), to calculate (in software 315 operating on processor 311) the amount of load that is not monitored or controlled by load iNodes 321 by subtracting from the total the total load that is monitored by load iNodes 321. Analogously, if source iNode 322 is measuring a non-zero amount of generated power, the total unmonitored load can be calculated by subtracting from the smart meter reading the total of load iNode readings and adding in all source iNode readings. This capability is useful because it allows unmonitored loads to be accounted for, and in some cases users could be prompted to secure (stop) unmonitored loads in a demand reduction scenario, in effect adding a manual load reduction capability that can be mediated by gateway iNode 315. There are any number of uses to which a system comprising an integrated smart meter 410, gateway iNode 310, and a variety of load and source iNodes 321 and 322 can be put, according to various embodiments of the invention. For example, if a utility sends a demand response signal directing the user corresponding to smart meter 410 to reduce a certain amount of load immediately, this reduction can be managed by gateway iNode 310. Gateway iNode 310 could carry out the requested demand reduction in a variety of ways. It could direct one or more load iNodes 331 to interrupt their power (that is, to turn off their loads), to provide some of the required reduction. It could direct source iNode 322 to actuate its control of electrical source 332 in order to start the generator or to increase the amount of electricity it generates. It could even coordinate, over data network 301, with other gateway iNodes to request that they shed some of the load cooperatively (of course, issues of verifiability will arise in such a scenario, and particularly of verifiability of non-duplication: the same load reduction should not be counted twice).

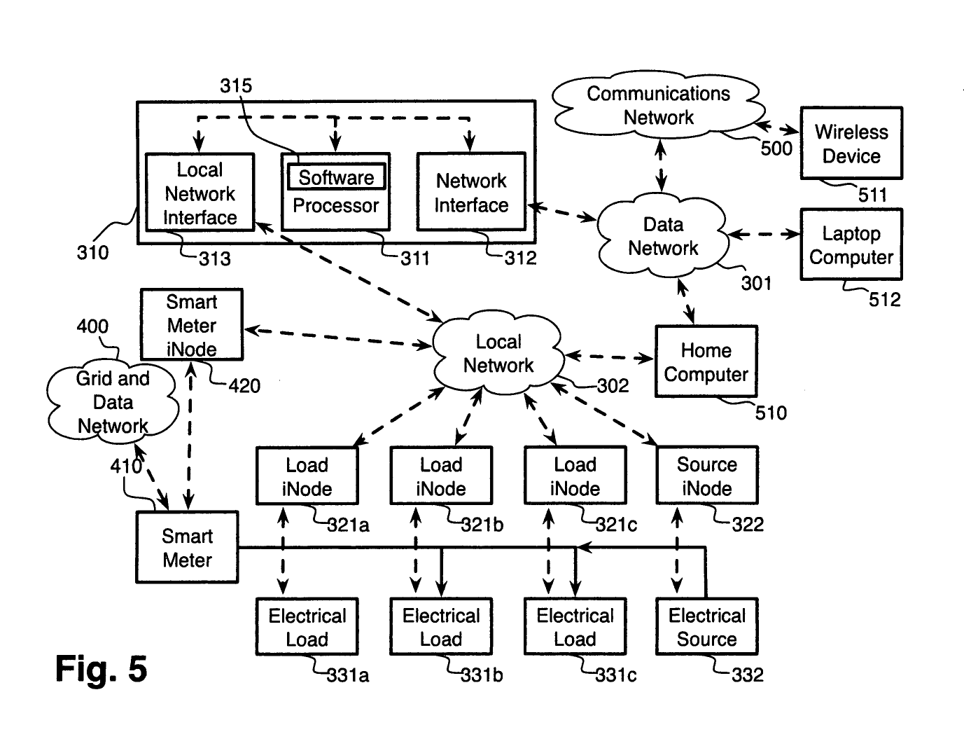

FIG. 5 illustrates several (although by no means all) of the ways in which human users can interact with home or small business energy management networks according to embodiments of the invention. In a preferred embodiment of the invention, a user accesses information, establishes preferences, and takes actions concerning energy management using home computer 510. Home computer 510 may be a desktop personal computer, a laptop, a “netbook” (a small portable computer with wireless data networking built in and limited capabilities), or any other general purpose computer. Home computer 510 may be connected separately to local network 302 and to external data network 301 (for instance, the Internet), or it may be connected to both through a broadband router, as is common in the art (that is, with this common configuration, home computer 510 can access other computing devices including possibly various iNodes via local network 302 and remote data sources via external data network 301 using a single network interface card that is connected to a broadband router. In some embodiments, gateway iNode 310 may connect to home computer 510 only via the Internet (often through the use of a remote website operated by another entity for the purpose of allowing homeowners and small business operators to manage their energy management networks. This approach would be common where, for example, local network 302 is a specialized wireless network based on a standard such as 802.15 or Zigbee™; desktop computers are typically not equipped to interface with such networks. In other embodiments, users may interact with their home energy management networks from remote locations using laptop or handheld computers 512 and communicating over external data network 301 (for example, the Internet); in other embodiments, users may interact using mobile devices connected over communications network 500 (typically a wireless network with data capabilities, as are common in the art today). Wireless device 511 could be a laptop computer equipped with a cellular modem (or wireless broadband access card), a mobile phone (especially, but not necessarily, a smart phone such as an iPhone™ from Apple, a Blackberry phone, or a phone based on Google's Android operating system), or a handheld computer equipped with wireless connectivity. Interaction using any of the devices shown in FIG. 5, or any comparable devices known in the art capable of acting as communicating data processing devices, may be accomplished using web browsers (when a third party service or a gateway iNode 310 provides web-based access services), or a dedicated software application that is adapted to interface using appropriate protocols with gateway iNode 310 or a third party service that mediates access to gateway iNode 310.

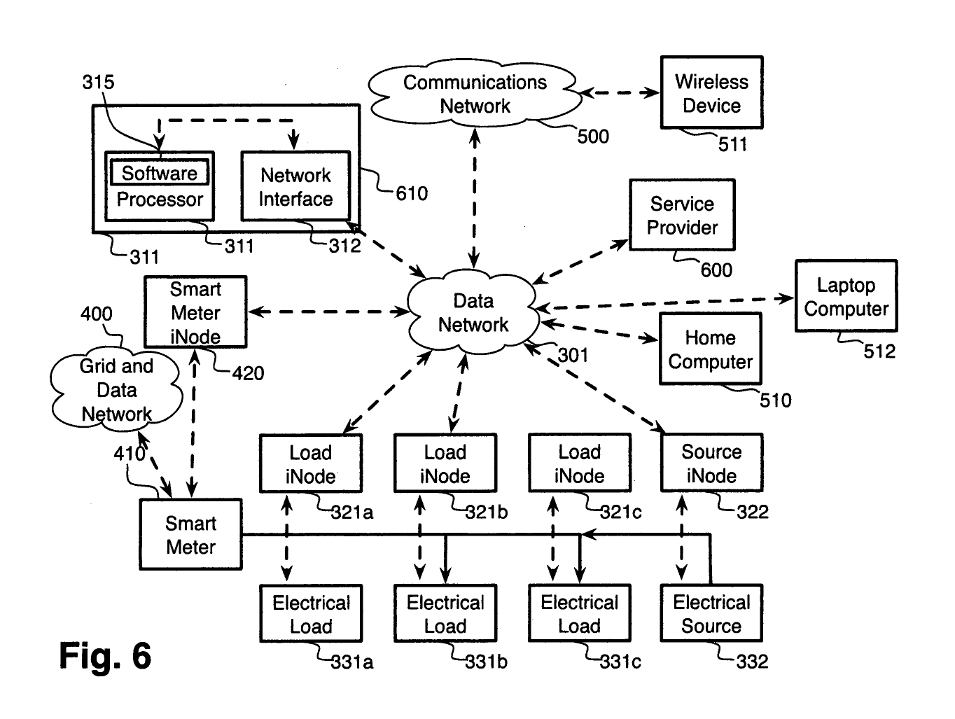

According to an embodiment of the invention, and illustrated in FIG. 6, iNodes are connected directly to external data network 301 rather than being connected through gateway iNode 610. Accordingly, gateway iNode 610 is only required in this embodiment to have one network gateway (although obviously a gateway iNode 310 with two network interfaces could be used, with one of the interfaces merely remaining idle). Also, although not shown separately, in another embodiment a mixed approach is taken: some iNodes connect to the external network 301 via a gateway iNode 310 with two network interfaces, while others connect directly to external data network 301 as shown in FIG. 6. While load iNodes 321, smart meter iNode 420, and source iNodes 322 could be hard-wired to connect only to gateway iNode 610 over external data network 301, in some embodiments local iNodes would connect to a service provider 600 over external data network 301, and identify themselves, for instance by each iNodes' providing a unique serial number to service provider when first connecting. The system disclosed in FIG. 6, like all embodiments of the invention described herein, is not limited to use in a particular type of venue such as homes or small businesses; the use of homes and small businesses is exemplary and not limiting. For example, load iNodes 321 could be a large number of dispersed electrical loads possibly under the economic control of a large number of entities. For instance, laptop charging stations in public places could be deployed by the owners or operators of the various public places, and made accessible to third party users such as travelers or coffee shop visitors via service provider 600. In some embodiments, patrons wishing to recharge laptops would connect via data network 301 to service provider 600 and make a small payment (or a donation to a charity), and service provider 600 would then send a signal to enable a corresponding electrical device 331 (i.e., outlet) allowing the patron to recharge. In another embodiment, such patrons could identify themselves and their utility provider and account number, and any electricity usage in (for example) electrical load 331a would be measured by iNode 321a and passed to service provider 600, who could then pass the data on to an appropriate utility provider for billing (possibly collecting a percentage fee which may then possibly be shared with the owner or manager of the location at which the charging patron is located). This example should make clear that there are many economic scenarios enabled, envisioned and encompassed by the invention, and it is reiterated that these examples should not be considered as limiting the scope of the invention.

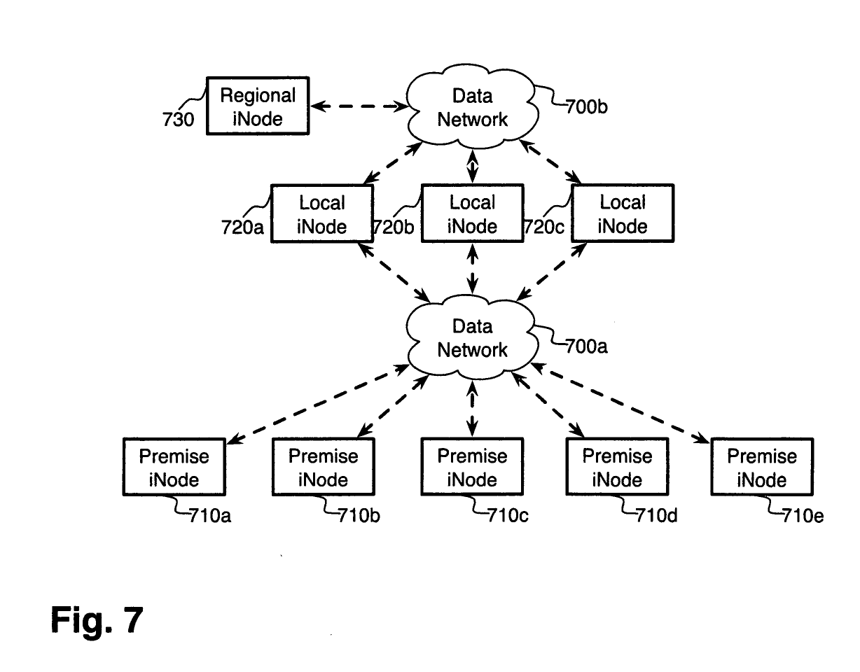

In a preferred embodiment of the invention, illustrated in FIG. 7, a hierarchical arrangement of iNodes is illustrated. A plurality of premise iNodes 710 is connected to one or more local iNodes 720 via data network 700a. Optionally, a plurality of local iNodes 720 is connected to one or more regional iNodes 730 via data network 700b. Many permutations and combinations are possible. Premise iNodes commonly, in embodiments of the invention, have child iNodes corresponding to particular electrical loads, sources, and so forth. As an example, premise iNode 710a may be a gateway iNode of a home energy management network of a type such as those illustrated in FIGS. 3-6. It could be a gateway iNode for a tenant in a commercial office building. It could be a gateway iNode for a single building in a college campus or a high school. It could be an isolated source iNode for a diesel generator normally used as an emergency power supply for a large retail establishment but configured to start on demand under control of a local utility during extreme demand periods. Similarly, local iNodes 720 could be of many types and could have many purposes, without departing from the scope of the invention. For example, a local iNode 720b could be a neighborhood cooperative energy management system's central node, receiving inputs from a utility (regional iNode 730 in this example) concerning desired demand levels, and from a plurality of home gateway iNodes 710. The neighborhood energy management system could coordinate among the participating neighborhood residents' premise iNodes 710 to, for example, coordinate the starting of heat pumps and air conditioning compressors during periods of high heat load (which are usually also periods of high electricity demand), in order to ensure that no two compressors or heat pumps start within a specified time of each other (heat pumps, compressors, and the like have high starting currents, and when many attempt to turn on nearly simultaneously, large load spikes can be experienced that can destabilize grid operations). Neighborhood management systems could also coordinate to ensure that the overall energy usage of a particular neighborhood does not exceed some specified limit (coordination is carried out by sending signals to premise iNodes 710 and in effect operating the premise iNodes and the local iNode as a distributed software system for optimizing energy usage profiles of the neighborhood as a whole). In another embodiment, one or more of premise iNodes 710 is a distributed storage system operated as a common asset of a local iNode's and its child iNodes; for instance, a neighborhood may invest in distributed battery storage systems, and possibly also in several generating devices, and these may be operated under control of local iNode 720b to manage overall load as viewed by regional iNode 730. Additionally, in such an arrangement, when prices are high due to high demand, local iNode 720b could direct generators and storage systems to deliver power to the members of the local community to avoid their having to pay the higher prices; storage could be “topped off” later when prices drop back to their normal, lower levels. This type of power management would actually be a boon to utilities as well as to their customers, as it is often quite expensive for them to deliver power during peak periods, and many of the ratepayers remain on fixed, regulated tariffs that are much lower than peak prices. In some embodiments, data networks 700a and 700b are identical (often the Internet serves both functions, but other single networks could also do so). It should be appreciated from these examples that the overlay packet data network approach of the present invention allows a wide range of deployment architectures, of which the examples given are a subset. For instance, there could be many layers of hierarchy, and a given premise iNode 710 could be logically connected to, and communicate with, and possibly even be controlled by, more than one local iNode 720, and a local iNode 720 could be connected to, communicate with, and possibly even be controlled by, more than one regional iNode 730. Or, in another embodiment, several distinct layers beyond the three layers shown in FIG. 7 are possible. And, in yet other embodiments, a given iNode may participate as a local iNode 720 with respect to certain applications or subnets, as a premise iNode 710 in other applications or subnets; that is, a given iNode could function at different hierarchical levels for different purposes. Moreover, in highly interconnected scenarios, it may be more useful to think of iNodes as being arranged in a web. And, since iNodes are generally associated with corresponding eNodes or physical elements of the underlying continuous flow energy distribution network (on top of which the overlay packet data network is overlaid), the architecture of large scale distribution of iNodes according to some embodiments of the present invention will often come to resemble the hub-and-spoke-with-hierarchical-subnets arrangement of typical large-scale electrical distribution systems.

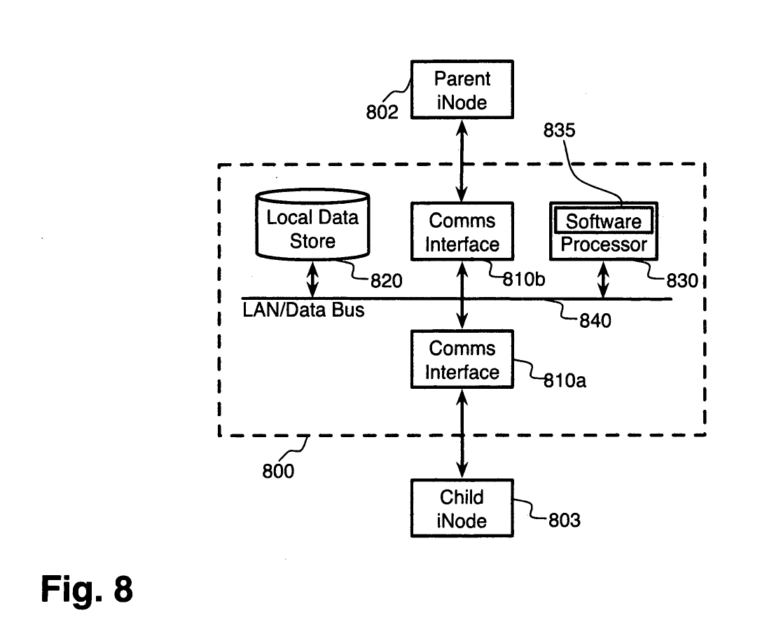

FIG. 8 shows an exemplary architecture, according to an embodiment of the invention, for intermediate iNodes 800 (intermediate in that they have both child iNodes 803 and parent iNodes 802, as for example the local iNodes 720 in FIG. 7). Like gateway iNodes 315, intermediate iNode 800 is equipped with one or more communications interfaces 810, depending on whether it needs to connect with more than one network. In some architectures, intermediate iNode 800 is connected to parent iNode 802 and child iNode 803 by the same data network 700. As with all iNodes, intermediate iNode 800 also comprises a processor 830 executing software 835. In some embodiments, intermediate iNode 800 also comprises a standalone local data store 820, above and beyond such basic storage as is generally associated with processor 830, and which is in many cases a relational database, but need not be. In many embodiments, since intermediate iNode 800 may be managing loads and sources (and data) from a large number of child iNodes 803, the functions of local data store 820, communications interfaces 810, and processor 830 may execute on physically separate machines connected by an internal data bus or local area network (LAN) 840. In some embodiments, local data store 820 is used to store configuration data for child iNodes 803 and intermediate iNode 800, such that, on startup, intermediate iNode 800 reads appropriate configuration data from local data store 820 and sets internal operating parameters accordingly. Additionally, intermediate iNode 800 may gather network addresses of child iNodes 803 and parent iNodes 802 with which it is associated on startup, and in some embodiments, upon gathering these address locations, intermediate iNode 800 initiates data communications with one or more of the child iNodes 803 and parent iNodes 802 whose addresses were obtained. Local data store 820 may also store transactional data concerning transactions such as demand response requests received from parent iNodes 802, demand response requests sent to child iNodes 803, or in another embodiment the identities of iNodes that bought generated power from a child source iNode 803. Since large numbers of intermediate iNodes of considerable computational power may be deployed in arbitrary network topologies including structures that can be described mathematically as highly-connected graphs, an overlay packet data network consisting of many low-level iNodes 803 associated with physical eNodes or energy resources and a rich set of intermediate and high-level iNodes 800, can be expected to be highly scalable, robust against incidental or maliciously-induced failures of any set of devices, and capable of computations of considerable complexity, such as the optimal routing of electricity throughout a nation-sized grid with many separate participating entities.

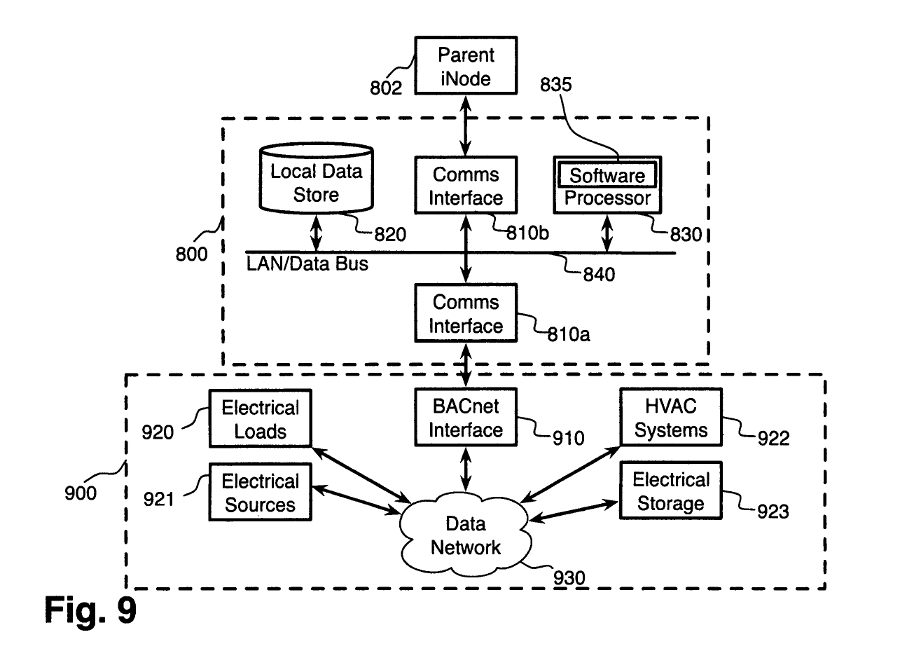

FIG. 9 illustrates another embodiment of the invention according to which a commercial building automation and energy management system 900 is integrated via an intermediate iNode 800. Many large commercial, institutional and industrial facilities already have quite sophisticated building automation and energy management systems 900 in the art. Commonly, these systems monitor, measure, and control HVAC systems 922, electrical storage devices 923 such as large-scale batteries, electrical sources 921 such as solar arrays or emergency generators, and of course myriad electrical loads 920. In many cases, building automation and energy management systems communicate internally, and make themselves accessible to external systems, by communications interfaces 910 using one of several standard data exchange protocols such as BACnet. There are several such protocols, including Lonworks and proprietary interfaces for particular control equipment manufacturers. In one sense, one may think of these large-scale systems as very large, complex electrical devices or eNodes 230, which have attributes common to electrical loads, sources and storage systems. Accordingly, under a preferred embodiment of the invention, an intermediate iNode 800 is closely coupled to a building energy management system 900 through communications between BACnet interface 910 and communications interface 810a, which is adapted to be able to pass BACnet messages to and from BACnet interface 910. Of course, Lonworks or other proprietary or open data exchange protocols used by building automation and energy management systems 900 can also be used instead of BACnet without departing from the scope of the invention.

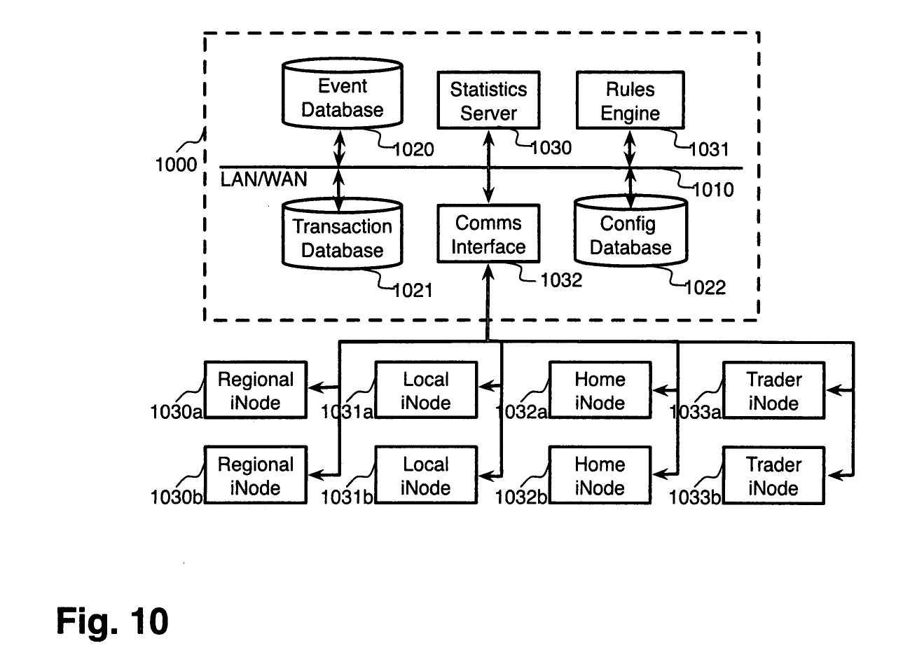

FIG. 10 illustrates a digital exchange 1000 according to an embodiment of the invention. A communications interface 1032 is adapted to communicate with a plurality of regional iNodes 1030, local iNodes 1031, home iNodes 1032, and trader iNodes 1033. Communications interface 1032 is adapted to provide one or more interface means for connection to remote iNodes. Interface means may support various standards such as HTTP, SOAP, RPC, XML, SCADA, VXML, and the like, or may be implemented in a proprietary way; the scope of the invention should not be taken as limited to any particular means of communication between the digital exchange 1000 and end users and their energy resources. Digital exchange 1000 may be implemented on a single server or other computing device, or its functions may be dispersed among several servers or computing devices as desired. The various modules of the digital exchange shown in FIG. 10 communicate with each other via a network 1010, which can be a local area network (LAN), a wide area network (WAN), the Internet, or any other network capable of providing for communication between the various elements of a digital exchange 1000.

A configuration database 1022 stores information pertaining to the configuration of the components of a digital exchange 1000, as well as information pertaining to users who have registered with the digital exchange 1000. When new users connect with a digital exchange via communications interface 1032 from a user interface via a remote iNode (1030, 1031, 1032, or 1033), they are guided through a registration process. Details of this process will vary in accordance with the invention, but will typically include at least the collection of identifying information concerning the user and information to enable the communications interface 1032 to connect to a remote iNode associated with the user, as appropriate. According to an embodiment of the invention, when a user provides information enabling a communications interface 1032 to find and connect to an associated remote iNode, the communications interface 1032 queries the remote iNode to obtain a list of devices or energy resources monitored and addressable by remote iNode. For instance, a home iNode 1032a may return a list of several loads and one or more generators or storage devices. Optionally, a user may view the list of associated devices or energy resources and provide detailed information about one or more of the devices or energy resources. For example, a user might start with a list of monitored outlets and appliances that was obtained by communications interface 1032 from home iNode 1032a, and manually provide the information that outlet #7 has a Dell Inspiron computer connected to it, outlet #8 has a 17-inch monitor connected to it, appliance #1 is a Kenmore washer of a specific model, and so forth. The list of “acquired” devices or energy resources, and all associated amplifying information concerning those devices or energy resources, are stored in configuration database 1022. According to an embodiment of the invention, configuration database 1022 is also populated with a set of data about the standard energy usage profiles of known brands and models of electric devices. For example, information may be stored in configuration database 1022 concerning the power consumption of various models of Kenmore washers and driers, as well as additional detailed information such as the various duty cycles and their associated power consumption profiles (the consumption of power by a washer, for instance, will vary dramatically at different stages of its various duty cycles). Information concerning precautions to be observed when considering deactivating particular devices is also optionally stored in configuration database 1022; for instance, it may be unsafe for a washer to turn it off during a spin cycle, whereas it might be perfectly safe to turn it off during a fill cycle.

According to a preferred embodiment of the invention, user preferences are stored in configuration database 1022. While interacting with digital exchange 1000, users are given options to express preferences for how their energy resources may (or may not) be used by a digital exchange 1000 to build response profiles and response packages or to execute energy management actions that involve the user's energy resources. As discussed above, preferences can be quite wide-ranging according to the invention, and may include mandatory preferences (preferences that a digital exchange is not allowed to violate, such as “never turn off my television on outlet #14”), or optional preferences with conditions (for example, “if the price is more than X degrees, and my hot water temperature is at least Y, and it is between 8:00 am and 4:00 pm local time, you can turn off my hot water heater for as long as needed or until the temperature drops to Z degrees”), or highly permissive preferences (“you can do whatever you want to this load, whenever you want”).

According to a preferred embodiment of the invention, events are stored in event database 1020. According to the invention, a very wide range of events may be stored in event database 1020. For example, each packet of data concerning the state of a device or energy resource can be considered an event and stored in event database 1020. To illustrate, consider a washing machine that is monitored and controlled by a home iNode 1032b in the home of a user of a digital exchange 1000. When the washing machine turns on, an event is generated to record that the device activated at a specific time. If the home iNode 1032b is configured to pass frequent power readings for the device, then a series of events of the form “device N was consuming X kilowatts at time T” is passed by home iNode 1032b via communications interface 1032 and stored in event database 1020. Similarly, if a response package is activated, and event is generated; if a particular response action is requested, an event is generated, and if the requested action is taken, another event is generated; all of these exemplary events are stored in event database 1020. It is desirable, according to the invention, to capture events at as granular a level as is possible for any given configuration (for example, as in the case of home iNode 1032b described above, it may only be possible to have information at the level of detail of a home, whereas in the case of another home iNode 1032a discussed above, device-level granularity is possible). According to the invention, configuration changes may also constitute events and be stored in event database 1020, enabling an audit trail to be maintained (that is, configuration database 1022 stores the current configuration but event database 1020 will have a complete record of changes to configuration database 1022). Extraneous events, which are events not directly recorded by remote iNodes, or other sources within the digital exchange infrastructure, may be entered manually or automatically into the event database 1020. For instance, if a third party provides weather forecast information or actual weather information (for example, “it is snowing in Wichita at time 1:00 pm”), this information can be stored in event database 1020. This is useful according to the invention because it may be possible to correlate changes in aggregate load across many connected users (connected to the communications interface 1320) with weather phenomena in a very detailed way.

According to a preferred embodiment of the invention, transaction database 1021 stores information pertaining to partial, pending, completed, and closed transactions. According to the invention, partial transactions may include transactions to which only one party is committed at a given point in time; for instance, an offer to sell the right to invoke a particular response package at a particular time in the future, or a request to obtain a specified level of demand reduction at a specified time in the future, when neither the offer nor the request has been taken up by a second party. Pending transactions according to the invention include situations where two parties are committed to a transaction but the underlying energy actions have not yet been consummated; for instance, if a utility has purchased the rights to invoke a response package at a specified time but either that time has not yet arrived or, if it has arrived, the utility has chosen to not execute the response package yet. Completed transactions are transactions for which the underlying energy resource actions have been taken. Closed transactions are transactions for which all settlement actions, such as verifying actual energy response actions taken, by user, allocating funds among various users who participated, and satisfying all financial aspects of the transaction for all parties involved, have been completed.

It should be appreciated by those practiced in the art that the various databases described herein are for illustrative purposes only. The functions of all of them can be included in a single database system, or the functions could be distributed over a larger number of database systems than outlined herein, without departing from the spirit and the scope of the invention. For example, a configuration database 1022 could contain only configuration information pertaining to physical things such as locations of remote iNodes, and consumer preference information could be stored in a separate preferences database, without departing from the scope of the invention. What is relevant to the invention is the set of information stored and the uses to which it is put, rather than precisely how it is stored; the field of database management is very advanced and those having practice in that art will appreciate that there are many considerations having nothing to do with the instant invention that may dictate one or another particular architectural approach to database storage.

According to an embodiment of the invention, statistics server 1030 calculates a plurality of statistics based on data take from or derived from one or more of a configuration database 1022, a transaction database 1021, and an event database 1020. Statistics can be calculated on request from clients of the statistics server 1030 such as a rules engine 1031 or remote iNodes provided via communications interface 1032. Statistics can also be calculated according to a prearranged schedule which may be stored in a configuration database 1022; alternatively statistics may be calculated periodically by statistics server 1030 and pushed to clients or applications which may then choose to use the passed statistics or not. According to an embodiment of the invention, statistics server 1030 is used to characterize an expected response profile of a plurality of end users of a digital exchange 1000, which response profile may be for a particular period of time or for any period of time; optionally time-specific and time-independent response profiles for a plurality of end users may both be calculated. According to another embodiment of the invention, statistics server 1030 is used to characterize expected response from a response package built up from a plurality of end user response profiles, which expected response may be for a particular period of time or for any period of time; optionally time-specific and time-independent response forecasts for a plurality of response packages may both be calculated. Statistics can be stored in a separate database such as an event database 1020, or they may be delivered in real time to a requesting client or application such as a rules engine 1031.

According to various embodiments of the invention, statistics server 1030 calculates statistics based on a wide variety of available input data. For example, statistics server 1030 can calculate the expected load reduction to be delivered by a single end user or a collection of end users on receipt of a request for a reduction in load. This may be calculated based on any available data from event database 1020, transaction database 1021, configuration database 1022, or any other data source accessible to statistics server 1030 (for instance, weather data passed directly in to statistics server from a third party via communications interface 1320). Data elements which may be used to calculate response profiles may include, but are not limited to, past history of responses to similar response requests at the same or different times and on the same or different days. Response profiles can be calculated based on a type of load to be reduced; for example, if a user has volunteered to make several resistive loads such as water heaters and resistive space heaters available for reduction on demand, expected response may be calculated by estimating the probability that said loads are actually active at the time of a request, based on previous history of the activation times for said loads. Alternatively, said resistive loads might always be on, yet an end user might occasionally override response actions locally, and statistics server 1030 may estimate likely load reduction by estimating the probability that an end user will override a demand reduction signal based on previous override history. In both of these examples, and indeed in any statistical calculation made by statistics server 1030, previous history data can be for the user concerning whom a statistics is being calculated, or it can optionally be historical data from a plurality of users who are judged by statistics server 1030 to have similar characteristics. This allows, for instance, a new user to be incorporated readily into the system and methods of the invention by allowing historical data for already-active users with similar characteristics to be used to estimate the expected behaviors of said new user. In an embodiment of the invention, demand management may be achieved by altering duty cycles of appropriate loads rather than merely turning them off; for example, setpoints of an advanced thermostat could be adjusted by one or more degrees in order to reduce the aggregate HVAC load controlled by the thermostat, or a hot water heater could be allowed to stay offline until water temperature drops to some predefined temperature, at which point the heater would turn on. In these cases, the preferences are stored in a configuration database 1022, and statistics server 1030 calculates expected response by, for example, deriving a response function, expressed as a function of time (where time can be defined in various ways, such as the time since the last duty cycle started, the time since a critical parameter was last reached, or the time from the response request's transmission to the device; this list is not exhaustive and should not be taken as limiting the scope of the invention), which characterizes the typical response for the device. Then, a calculation of the likely response can be made using this function and included in a response profile. Note also that whenever information about a device type, such as a particular type or model of washer, dryer, thermostat, or any other device, is contained in a configuration database, information from either the manufacturer of a device or an aggregated history from many such devices used by various participants in digital exchange 1000, can be used in lieu of actual usage information from any particular user if desired. In this way, response profiles can be built up with high accuracy for even very new users (or for users who do not have equipment that enables current or power measurements per device, as upon listing various devices a response profile can be built using typical response profiles for each device the user lists).

In another embodiment of the invention, expected response profiles can be based at least in part on information that is either real time in nature or nearly so. For example, when information about current status of equipment (on or off, and potentially at which point in a duty cycle) can be gathered, it can be used to modify a response profile by taking into account the fact that loads which are already off cannot be turned off to save power. Similarly, scheduled loads, when known to statistics server 1030 (by being stored in configuration database 1022), can be leveraged by taking into account the fact that a given load is scheduled to turn on in a period of interest, and overriding the schedule to keep it off, thus achieving a predictable load reduction for the period of interest.

In another embodiment of the invention, users can be assigned an “energy risk rating” analogous to a credit rating. Statistics server 1030 calculates energy risk ratings by taking into account past user history, particularly concerning the degree to which a user honors his commitments. For example, if a user volunteers (by establishing preferences that are stored in configuration database 1022) to allow 3 kilowatts of load to be controlled by digital exchange 1000 during periods of demand response (or by volunteering to provide generated power of 3 kilowatts from a home wind turbine), and then fails to actually deliver according to what was volunteered (either because devices were off and therefore not available for load shedding, or wind was not available, or any other reason), then statistics server 1030 decrements the energy risk rating for said user. As with credit scores, time can be a key parameter in adjusting energy risk ratings; after a series of failed commitments, it takes some time before the energy risk rating will rise back up following a change to actually honoring commitments.

It should be appreciated that the examples of statistical data generation provided heretofore are exemplary in nature and do not limit the scope of the invention. Essentially any statistics that can be calculated based on data available about users, their loads and available energy resources, their behaviors (for instance, one might be able to infer that a user is at home based on dynamic behavior of power usage, and use this to predict how responses might differ from those of a user away from home; in fact, preferences can be stated according to away or at home profiles, which can be inferred or directly declared as is done with home security systems when a user clicks “Away” to tell the system he is leaving the house), the consistency of their responses, their demographics, and so forth.

According to a preferred embodiment of the invention, rules engine 1031 or an equivalent software module capable (equivalent in the sense that it meets the functional description provided herein, which is often done using a standards-based rules engine, but need not be so limited) receives events or notifications from one or more of the other components of the invention and executes any rules linked to said events or notifications. Events could be received from a third party via communications interface 1032 (as when a user elects to invoke a response package that he has purchased through digital exchange 1000), or from statistics server 1030 (as when a statistic exceeds some configured threshold), or from one of the databases (as when a data element is added or changed). Events can also occur, and fire rules, based on calendars; for instance, a daily event might fire which causes a new set of response packages, for times during the day that is one week or one month in the future, to be created and stored in configuration database 1022 (and made available for purchase on digital exchange 1000 via communications interface 1320). When an event is received, an event handler in rules engine 1031 evaluates whether any rules are configured to be fired when an event of the type received occurs. If so, rules are executed in an order stipulated, as is commonly done with rules engines. Rules can generally invoke other rules, so an event's firing may cause a cascade of rules to “fire” or execute; rule invocation and execution continues until no further rules are remaining to be fired. Rules are stored alternatively either in the rules engine 1031 itself, or in configuration database 1022. In an embodiment of the invention, rules are established for the management of response packages, so that when a user changes or adds configuration data relating to loads or energy resources that can be controlled by digital exchange 1000, a rule is fired which causes the user's response profile to be recalculated and the revised response profile to be stored in configuration database 1022. Typically, whenever a response profile is added or changed, a rule will fire which either recalculates the expected statistical behavior of any response packages of which the changed user's response profile is an element, or determines if the newly added or changed response profile should be added to an existing or a new response package. Inclusion of a response profile in a response package may be based on a number of factors, including but not limited to the geographic location of the facility (home or small business) associated with the new user (for instance, if all users within a given substation's service area are to be included in a single response package), the demographics of the user (for instance, if a response package comprised of “affluent greens” is maintained, and a new user matching that profile is added), or the type of generation equipment available at the new user's facility (for instance, if all wind power generators are bundled into a plurality of wind-based response packages). In this latter case, in an embodiment of the invention the wind profiles of the geographic locations of various users who together comprise a response package can be combined by statistics server 1030 into a composite wind generation response package profile that can then be used to announce to prospective buyers the availability of specified amounts of wind power at specified times. In some cases, there may be an insufficient number of response profiles in a given region, or of a given type, to make a reasonably sized (and reasonably well-behaved, which typically is a consequence of having a statistically significant mix of response profiles in a single response package) response package; in these cases, when a new user or set of resources (associated with an existing user) is added that is in the same region or has the same type, a rule is triggered which checks to see if there are now enough users, or enough load (or generating capacity) to create a new response package. If the answer is yes, then a new response package is created, and a request is sent to statistics server 1030 to calculate the expected responses of the new response package. When the results are returned from the statistics server 1030, they are stored in configuration database 1022 and any rules for making the response package available via communications interface 1320 are invoked. In this fashion (and through the use of scheduled events as discussed above), an inventory of available response packages is made available to potential buyers on digital exchange 1000.

Another example of rules which are triggered by events according to the invention is when a demand for service is placed at the digital exchange 1000. In an embodiment of the invention, when a consumer's preference, stored in configuration database 1022, states that a given load should only be operated when power of a certain type is available (for instance, “don't run my dishwasher except using wind power”), and the consumer desires to operate the given load, then a request is placed to the digital exchange 1000 for a package of wind power of sufficient quantity to provide for the given load. The placement of such a request constitutes an event which is stored at event database 1020 and passed to rules engine 1031 to determine if any rules are fired by the event. In this case, a rule would be fired which determines if there is any wind power available in sufficient quantity to provide for the given load. If not, a message is sent via communication interface 1320 to the appropriate remote iNode to so inform the user. If there is a single source of wind suitable for the given load, then the capacity of a response package associated with the source is decremented for the relevant time interval (it could be the current time interval or a future time interval, for example when the given load is to be operated according to a schedule at a future time) by an amount equal to the expected demand from the given load. If there is more than one suitable source available for the given load, then the rule that was invoked will either resolve the situation itself if it is so designed, or it will invoke a further rule to select from among a plurality of sources the one that is most appropriate. Selection of sources can be made according to any criteria, including but not limited to price, proximity to the requesting user, energy risk rating of the various response packages, or a fairness routine that spreads equally priced demand among a plurality of sources of supply.

It should be appreciated that the examples of rules provided in the above are exemplary only and should not be taken to limit the scope of the invention. Rules engine 1031 is the module that responds to events and that in effect creates an efficient market for energy based on aggregated response packages, which are in turn based on the detailed statistical behaviors of a plurality of individual users, loads and energy resources.

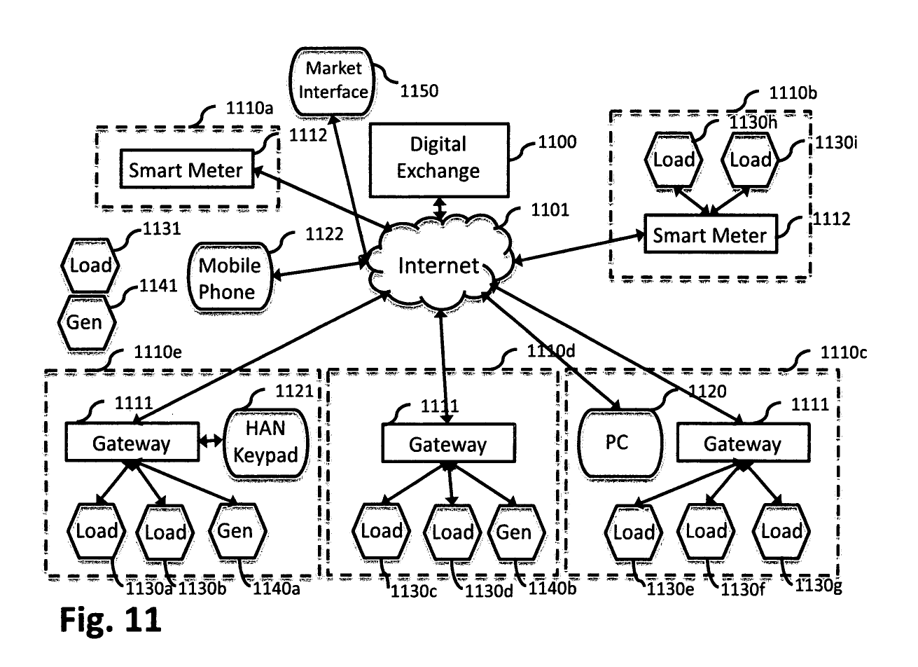

FIG. 11 illustrates a network architecture according to a preferred embodiment of the invention. A digital exchange 1100 acts as a control point according to an embodiment. Users such as small businesses and consumers participate by interacting with the digital exchange 1100. Interaction is normally conducted by connecting to the digital exchange 1100 via the Internet 11011, although this is not necessary according to the invention. Interaction between users and the digital exchange 1100 can be conducted by any suitable communications medium, such as wired or wireless telephony. In various embodiments of the invention, users interact with the digital exchange 1100 through the use of mobile phones 1122, personal computers (PCs) 1120, or a home area network (HAN) keypad 1121 such as might be used as part of a home automation system. While according to a preferred embodiment of the invention interaction data such as preferences or requested actions are passed over the Internet 1101 to and from users via one or more of these various devices, it should be appreciated that web-based services can today be delivered over a large and growing number of device types and communications networks without departing from the scope of the invention. For instance, a user could establish a multimodal voice-and-data session from a “smart mobile phone” over both the Internet 1101 and the wireless telephony network, and use both voice and data channels to interact with a digital exchange 1100 according to the invention. Furthermore, some market participants (that is, participants in an energy market established according to the invention through a digital exchange 1100), such utilities or energy aggregators, may interact with a digital exchange 1100 either directly or over the Internet 1101 from a market interface 1150. In some embodiments, market interface 1150 is a dedicated server operating software adapted to communicate with the digital exchange 1100 via hypertext transfer protocol (HTTP), extensible markup language (XML) or a specialized protocol using XML, remote procedure calls (RPC), the SOAP web services protocol, or any of a number of well-established data integration methods well-known in the art. Consumers and small business owners interact with a digital exchange 1100 in order to identify and authenticate themselves, to identify energy resources (for example, loads such as appliances, computers, hot tubs, etc., supply-side resources such as storage devices or generators, although the invention should be understood to encompass any energy resources capable of being controlled by homeowners or small business operators), and to establish preferences concerning how and when any resources so identified are to be available actions requested by the digital exchange 1100. Examples of preferences that might be expressed according to the invention are levels of criticality of loads, minimum prices at which resources are to be considered available for use, special times of day or particular days when specific resources (or even all resources) are to be considered available for use (or to be not available for use). In general, the invention should not be considered limited to any particular set or sets of preferences, as any preferences that may be useful to a particular user or groups of users and that is capable of being honored by a digital exchange 1100 are permissible according to the invention. Users may also establish preferences concerning what amount of data concerning a user or his energy resources a digital exchange 1100 is allowed to retrieve, and under what conditions (length of time, degree of anonymity, and the like) such data is to be allowed to be retained by a digital exchange 1100.

According to an embodiment of the invention, a home or small business 1110c comprises a plurality of electric loads 1130 that are connected to, and draw electric power from, an electric grid 1160. At least some of loads 1130 are further adapted to communicate with a gateway 1111. Electric loads 1130 can be any kind of electric load capable of being operated in a home or small business, such as major appliances (washers, driers, and the like), electronics (computers, stereos, televisions, game systems, and the like), lighting, or even simply electric plugs (which can have any actual load “plugged into” it, or no load at all). In some embodiments, loads 1130 have current sensing and control circuitry capable of communicating with a gateway 1111 built in (for example, “smart thermostats” and “smart appliances”, which are well-known in the art); in other cases, loads 1130 may be connected through wall sockets, surge suppressors, or similar switching devices, which are adapted to be able to communicate with a gateway 1111. In some embodiments, information about the current or power flowing through a load 1130 is passed to a gateway 1111. In other embodiments, only information about the status of the load, such as whether it is on or off, is provided to a gateway 1111. Communications between gateway 1111 and loads 1130 can be wireless, using a standard such as the ZigBee wireless mesh networking standard or the 802.15.4 wireless data communications protocol, or can be conducted using a wired connection using either power lines in the home or small business (broadband over power lines) or standard network cabling. The actual data communications protocol used between a gateway 1111 and a load 1130 may be any of the several data communications protocols well-known in the art, such as TCP/IP or UDP. According to an embodiment of the invention, a gateway 1111 is connected via the Internet 1101 to a digital exchange 1100 using an Internet Protocol (IP) connection; as with communications between user interface devices and a digital exchange 1100, communications between a gateway 1111 and a digital exchange 1100 can be established using any of the means well-known in the art, including but not limited to HTTP, XML, SOAP, and RPC.

In an embodiment of the invention, a home or small business 1110c communicates with a digital exchange 1100 via the Internet 1101 or a similar data network. According to the embodiment, data is pushed from a gateway 1111 to a digital exchange 1100 in order to provide information concerning condition of loads 1130. For example, gateway 1111, at a specified time interval, may report to digital exchange 1100 that load 1130e is running and using 1.5 amps of current (or 180 watts of power), and that load 1130f is off, and that load 1130g is running in power-conservation mode (for example, if load 1130g is a computer and is adapted to provide its energy-management mode to a gateway 1111). In other embodiments, gateway 1111 may pass periodic updates to digital exchange 1100 and supplement the regular updates with event-based updates (for example, when a load 1130f turns on). In yet other embodiments, digital exchange 1100 pulls data from gateway 1111 either on a periodic basis or on an as-needed basis. It will be understood by those having ordinary skill in the art that many combinations of push and pull, periodic and event-driven update strategies may be used by one or more gateways, or by a single gateway at different times, or indeed even by a single gateway at one time, with different techniques being used for different loads. Users in a home or small business 1110c can communicate with the digital exchange 1100 as described above using a PC 1120, a telephone such as a mobile phone 1122, a dedicated home area network keypad 1121, or directly on gateway 1111, which can alternatively be equipped with a screen such as an LED screen or a touchpad, and optionally with buttons, sliders and the like for establishing preferences that are then transmitted to the digital exchange 1100.

According to another embodiment of the invention, a home or small business 1110c comprises a plurality of electric loads 1130 that are connected to, and draw electric power from, an electricity grid 1160, and further comprises a plurality of generation and storage devices 1140 that are connected to, and adapted to provide power to, an electricity grid 1160. At least some of loads 1130 and generators 1140 (taken here to include storage devices that can provide electricity on demand to the grid 1160) are further adapted to communicate with a gateway 1111. Electric loads 1130 can be any kind of electric load capable of being operated in a home or small business, such as major appliances (washers, driers, and the like), electronics (computers, stereos, televisions, game systems, and the like), lighting, or even simply electric plugs (which can have any actual load “plugged into” it, or no load at all). In some embodiments, loads 1130 have current sensing and control circuitry capable of communicating with a gateway 1111 built in (for example, “smart thermostats” and “smart appliances”, which are well-known in the art); in other cases, loads 1130 may be connected through wall sockets, surge suppressors, or similar switching devices, which are adapted to be able to communicate with a gateway 1111. In some embodiments, information about the current or power flowing through a load 1130 is passed to a gateway 1111. In other embodiments, only information about the status of the load, such as whether it is on or off, is provided to a gateway 1111. Electricity generators 1140 can be any kind of device capable of providing power to an electricity grid 1160, including but not limited to wind turbines or other wind-driven generators, photovoltaic cells or arrays or other devices capable of converting sunlight into electricity, electricity storage devices such as batteries and pumped hydro storage facilities, and the like. Communications between gateway 1111 and loads 1130 and generators 1140 can be wireless, using a standard such as the ZigBee wireless mesh networking standard or the 802.15.4 wireless data communications protocol, or can be conducted using a wired connection using either power lines in the home or small business (broadband over power lines) or standard network cabling. The actual data communications protocol used between a gateway 1111 and a load 1130 or a generator 1140 may be any of the several data communications protocols well-known in the art, such as TCP/IP or UDP. According to an embodiment of the invention, a gateway 1111 is connected via the Internet 1101 to a digital exchange 1100 using an Internet Protocol (IP) connection; as with communications between user interface devices and a digital exchange 1100, communications between a gateway 1111 and a digital exchange 1100 can be established using any of the means well-known in the art, including but not limited to HTTP, XML, SOAP, and RPC.

In an embodiment of the invention, a home or small business 1110c communicates with a digital exchange 1100 via the Internet 1101 or a similar data network. According to the embodiment, data is pushed from a gateway 1111 to a digital exchange 1100 in order to provide information concerning condition of loads 1130 and generators 1140. For example, gateway 1111, at a specified time interval, may report to digital exchange 1100 that generator 1140b is running and generating 500 watts of power, and that load 1130c is off, and that load 1130d is running in power-conservation mode (for example, if load 1130d is a computer and is adapted to provide its energy-management mode to a gateway 1111). In other embodiments, gateway 1111 may pass periodic updates to digital exchange 1100 and supplement the regular updates with event-based updates (for example, when a load 1130c turns on). In yet other embodiments, digital exchange 1100 pulls data from gateway 1111 either on a periodic basis or on an as-needed basis. It will be understood by those having ordinary skill in the art that many combinations of push and pull, periodic and event-driven update strategies may be used by one or more gateways, or by a single gateway at different times, or indeed even by a single gateway at one time, with different techniques being used for different loads. Users in a home or small business 1110d can communicate with the digital exchange 1100 as described above using a PC 1120, a telephone such as a mobile phone 1122, a dedicated home area network keypad 1121, or directly on gateway 1111, which can alternatively be equipped with a screen such as an LED screen or a touchpad, and optionally with buttons, sliders and the like for establishing preferences that are then transmitted to the digital exchange 1100.

According to another embodiment of the invention, a home or small business 1110b comprises a plurality of electric loads 1130 that are connected to, and draw electric power from, an electric grid 1160 via a connecting smart meter 1112 that is adapted to meter electricity usage within home 1110b. At least some of loads 1130 are further adapted to communicate with a smart meter 1112. Electric loads 1130 can be any kind of electric load capable of being operated in a home or small business, such as major appliances (washers, driers, and the like), electronics (computers, stereos, televisions, game systems, and the like), lighting, or even simply electric plugs (which can have any actual load “plugged into” it, or no load at all). In some embodiments, loads 1130 have current sensing and control circuitry capable of communicating with a smart meter 1112 built in (for example, “smart thermostats” and “smart appliances”, which are well-known in the art); in other cases, loads 1130 may be connected through wall sockets, surge suppressors, or similar switching devices, which are adapted to be able to communicate with a smart meter 1112. In some embodiments, information about the current or power flowing through a load 1130 is passed to a smart meter 1112. In other embodiments, only information about the status of the load, such as whether it is on or off, is provided to a smart meter 1112. Communications between smart meter 1112 and loads 1130 can be wireless, using a standard such as the ZigBee wireless mesh networking standard or the 802.15.4 wireless data communications protocol, or can be conducted using a wired connection using either power lines in the home or small business (broadband over power lines) or standard network cabling. The actual data communications protocol used between a smart meter 1112 and a load 1130 may be any of the several data communications protocols well-known in the art, such as TCP/IP or UDP. According to an embodiment of the invention, a smart meter 1112 is connected via the Internet 1101 to a digital exchange 1100 using an Internet Protocol (IP) connection; as with communications between user interface devices and a digital exchange 1100, communications between a smart meter 1112 and a digital exchange 1100 can be established using any of the means well-known in the art, including but not limited to HTTP, XML, SOAP, and RPC.

In an embodiment of the invention, a home or small business 1110c communicates with a digital exchange 1100 via the Internet 1101 or a similar data network. According to the embodiment, data is pushed from a smart meter 1112 to a digital exchange 1100 in order to provide information concerning condition of loads 1130. For example, smart meter 1112, at a specified time interval, may report to digital exchange 1100 that load 1130e is running and using 1.5 amps of current (or 180 watts of power), and that load 1130f is off, and that load 1130g is running in power-conservation mode (for example, if load 1130g is a computer and is adapted to provide its energy-management mode to a smart meter 1112). In other embodiments, smart meter 1112 may pass periodic updates to digital exchange 1100 and supplement the regular updates with event-based updates (for example, when a load 1130f turns on). In yet other embodiments, digital exchange 1100 pulls data from smart meter 1112 either on a periodic basis or on an as-needed basis. It will be understood by those having ordinary skill in the art that many combinations of push and pull, periodic and event-driven update strategies may be used by one or more gateways, or by a single gateway at different times, or indeed even by a single gateway at one time, with different techniques being used for different loads. Users in a home or small business 1110c can communicate with the digital exchange 1100 as described above using a PC 1120, a telephone such as a mobile phone 1122, a dedicated home area network keypad 11211, or directly on smart meter 1112, which can alternatively be equipped with a screen such as an LED screen or a touchpad, and optionally with buttons, sliders and the like for establishing preferences that are then transmitted to the digital exchange 1100. It will be appreciated that the description above of the communications associated with a home or small business 1110d comprising both loads and generators is equally applicable to homes or small businesses in which a smart meter 1112 is used in place of a gateway 1111, with a smart meter 1112 performing similar functions to a gateway 1112 in addition to its normal role of metering power usage.

In some cases, homes 1110a may only pass aggregate electricity consumption data to a digital exchange 1100 from a smart meter 1112, either via the Internet 1101 or a special-purpose data communications network adapted for communications between smart meters 1112 and utility-based data systems. In these cases, even though there is no visibility at the digital exchange level to the individual loads and generators in homes 1110a, it is still possible according to the invention for a digital exchange to receive usage data (from smart meter 1112) and to send requests for action (for instance, via a text message to a mobile phone 1122 or even a phone call to a regular phone located at the home or small business 1110a, asking the consumer to shed unnecessary loads due to high electricity demand or to attempt to place any generating units online in response to a need at the electricity grid 1160). Since any changes in load measured by smart meter 1112 at home or small business 1110a would be sensed by digital exchange 1100 shortly after the request went out, the response profile of such smart meter-only users can be included in response packages according to the invention. Even further, it is possible to include entirely unmonitored loads 1131 and generators 1141 (again, taken to include storage systems capable of injecting power onto the grid 1160); “unmonitored” as used here means that the usage of loads 1131 and generators 1141 is not monitored in real time or near real time by digital exchange 1100. The use of unmonitored loads 1131 and generators 1141 can still be beneficial according to the invention. For example, in an embodiment of the invention some users register unmonitored loads 1131 and generators 1141 with the digital exchange 1100 using one of the user interface methods discussed earlier (for example, via a website associated with digital exchange 1100). Optionally, the registering user can also provide certified records of past operation of the unmonitored loads 1131 or generators 1141, which can be used according to the invention as input to be used in building a response profile for the unmonitored loads 1131 or generators 1141. These unmonitored response profiles can be included in larger response packages, with or without discounting of the capacity of the unmonitored loads 1131 or generators 1141 to account for the fact that these devices are unmonitored. Then, when a response package including such unmonitored loads 1131 or generators 1141 is activated, an activation message is sent to users of unmonitored loads 1131 and generators 1141 advising them of the required action to take. Messages are sent via any communications medium, including but not limited to phone calls, text messages, emails, or alerts on a website that may be monitored manually or automatically by users of unmonitored loads 1131 and generators 1141. Accounting for whether such users actually take the requested actions is done in two ways. First, the statistical profile of the response profile for such energy resources will include the expected behavior (for example, the action will be taken 55% of the times it is requested); this is used by digital exchange 1100 to build a response package that behaves as expected. Second, audits may be contractually required and conducted in which actual usage of unmonitored loads 1131 and generators 1141 is checked periodically (for example, monthly), by a third party or with sufficient safeguards against fraud as are needed to satisfy business needs of a digital exchange 1100. These needs will vary depending on the context. For example, some users of unmonitored loads 1131 and generators 1141 will want to voluntarily participate and expect no remuneration for their participation; in these cases, it is not important to have a level of confidence sufficient for the disbursement of funds, but only a level of understanding of expected behaviors to enable a refinement of the statistical model of the response profile. In other cases, users of unmonitored loads 1131 and generators 1141 will expect to be paid for their participation, and therefore will likely agree to contractual terms including right of audit, for example of tamper-proof device usage logs.

In another embodiment of the invention, one or more of loads 1130 are monitored by “clip-on” current measuring devices which are clipped around a load-bearing able in order to sense the current flowing through the cable. In an embodiment, the clip-on current sensor is adapted to monitor one or more phases of the main current flowing into a home or a small business, essentially acting (via its wireless connection to a gateway 1111) as a clip-on smart meter.

It will be seen from the various embodiments illustrated in FIG. 11 that essentially any arrangement of communications will suffice as long as it allows users of energy resources to establish their preferences, and operators of digital exchange 1100 to build statistical models of expected responses to requests to take action, and operators of digital exchange to send notification of requested actions to users of energy resources according to their preferences.

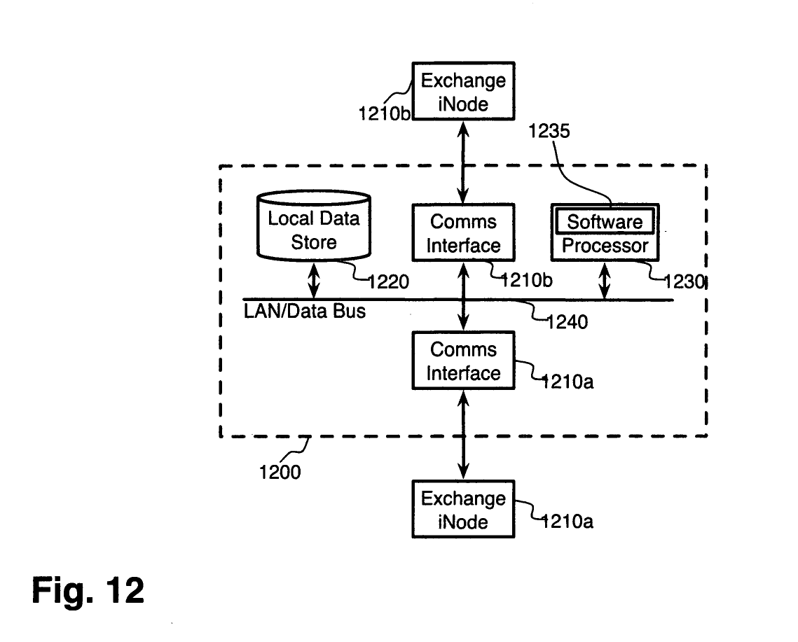

FIG. 12 shows a trading iNode 1200, according to an embodiment of the invention. As with most intermediate iNodes, trading iNode 1200 comprises a processor 1230 with software 1235 operating on it, and at least one communications interface 1210. Communications interfaces 1210a and optionally 1210b and others, are adapted to exchange data with one or more exchange iNodes 1210, which carry out functions substantially similar to those described with reference to digital exchange 1100 in FIG. 11. Trading iNode 1200 will typically make heavy use of transactional logic, and in most embodiments trading iNodes 1200 will also comprise a local data store 1220. While trading iNode 1200 can be implemented entirely within a single computer, in many embodiments it will be preferable to use dedicated computers for one or more of local data store 1220, communication interfaces 1210, and software 1235, and some of these may even be provided in plural form for scalability or fault tolerance. When more than one computer is used in trading iNode 1200, a data bus or local area network 1240 enables communication between the various computers as is well established in the art. In some embodiments, network 1240 may in fact be the Internet or an intranet of a trading firm or the like. Software of trading iNode 1200 in some embodiments may be adapted to perform analysis on electrical system data provided by one or more exchange iNodes 1210 or by external sources (not shown), such as paid information services. Other embodiments may include automated trading software 1235 operating on processor 1230 that analyzes data collected and stored in local data store 1220 (or externally) and, based on these analyses and trading rules established by the user of trading iNode 1200, makes trades automatically when rules or conditions are satisfied, on one more of exchange iNodes 1210.

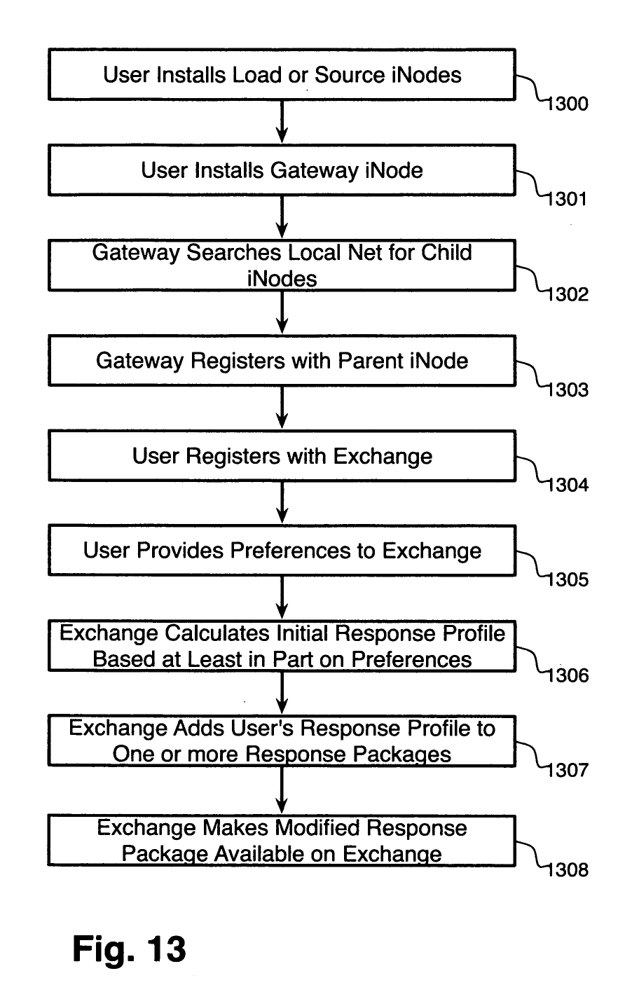

FIG. 13 outlines a method, according to an embodiment, for incorporating new users into a digital exchange 1100. In a preferred embodiment, a new user installs load iNodes 321 or source iNodes 322 in step 1300 to measure or manage one or more of the electrical resources under her control. In a second step 1301 the user installs gateway iNode 310 and the gateway, in step 1302, searches a local network for already-installed child iNodes 803 (typically those installed in step 1300). Once it has identified all of the installed iNodes that are visible to it and (optionally) configured to be controlled by it, in step 1303 gateway iNode 310 registers with a parent iNode 802. In some embodiments, gateway iNode 310 will have an address for a parent iNode 802 preconfigured in the device before it is distributed to users; in other embodiments users will have addresses of potentially relevant parent iNodes 802 available as part of the setup process. Typically gateway iNode 310, on registering with parent iNode 802, will upload a list of the identities and types of any child iNodes 803 it detected in step 1301. After installing gateway iNode 310 (which performs steps 1302 and 1303 autonomously under most embodiments, although this is not required), the user registers with digital exchange 1100, typically via a website provided with installation instructions. In most embodiments, newly registering users will be asked by digital exchange 1100 (or service provider 600, which could be any arbitrary third-party service provider; in some embodiments users register with intermediaries who participate in digital exchange 1100 on their behalf, without departing from the scope of the invention) to provide a serial number or other identifying information of the gateway iNode the user installed (in step 1301); this information allows digital exchange 1100 or service provider 600 to associate a human user with a set of iNodes (the gateway iNode 310 and its associated child iNodes 303). In optional step 1304, not necessarily performed immediately, a user is allowed to establish or provide a series of preferences to digital exchange 1100 or service provider 600, such as those discussed above concerning what demand management actions the user will allow. Based on these preferences (or, in their absence, based on default settings which may be based on a user's demographic profile), an initial response profile for the user is established in step 1306, generally by digital exchange 1100, which may have received relevant user-specific data from service provider 600. In step 1307, this response profile is optionally added by digital exchange 1100 to one or more response packages, which modified response packages may then be made available by digital exchange 1100 to its participants in step 1308.

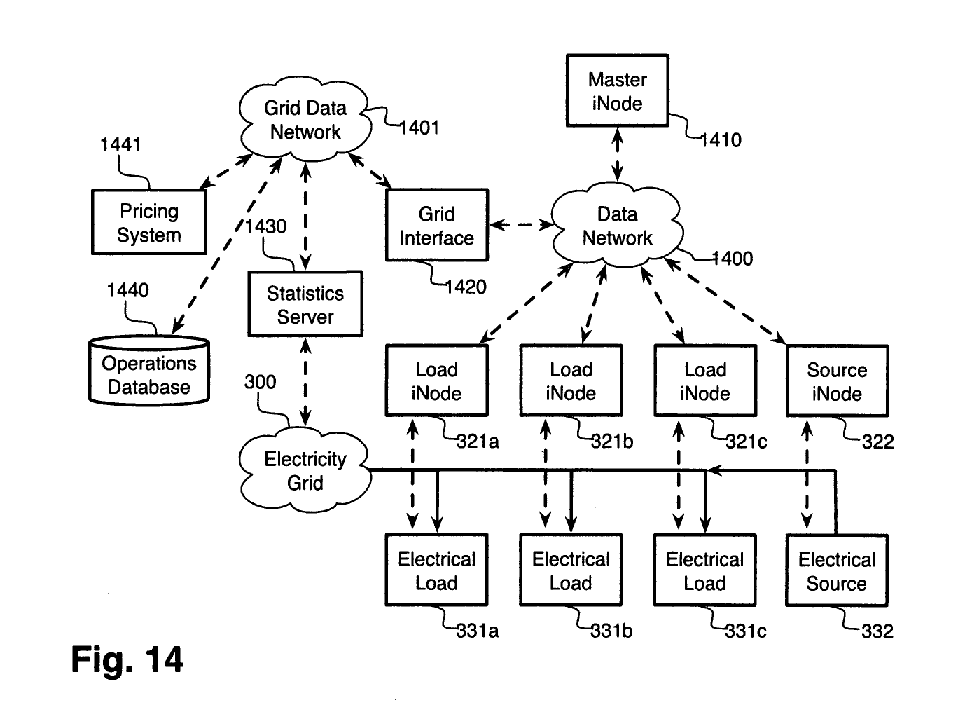

In a preferred embodiment, and referring to FIG. 14, a fractional smart metering system is disclosed. According to the embodiment, a plurality of electrical loads 331 and electrical sources 332 associated with one or more consumers of energy are monitored by associated load iNodes 321 and source iNodes 322 as described above in reference to FIG. 3. Each load iNode is adapted at least to record the energy usage in its associated electrical load 331, and each source iNode 322 is adapted at least to measure the energy generated by its associated electrical source 332. Load iNodes 321 and source iNodes 322 are connected via data network 1402 and master iNode 1410. Data network 1400 is in some embodiments a home area network or a local area network in a small business, but in other embodiments data network 1400 is the Internet. Master iNode 1410 receives from a plurality of load iNodes 321 and source iNodes 322 usage statistics concerning the consumption or generation of energy by the associated electrical loads 331 and electrical sources 332. As before, while in this example loads and sources are electrical in nature, it should be understood that they could also pertain to other types of energy such as natural gas, and the fractional smart metering system could be used to measure other forms of energy and to manage energy distribution networks other than electrical grids. Master iNode 1410 is adapted to receive usage statistics at predetermined time intervals, such as on a quarter-hourly basis, although master iNode 1410 in some embodiments is adapted to pull usage statistics on demand rather than to receive them periodically. Master iNode 1410 passes these aggregated usage statistics, which may optionally also include generation statistics, via grid interface 1420, to statistics server 1430, which is typically located in a utility operations center, but need not be. Statistics server 1430 is connected via grid data network 1401 to grid interface 1420; grid interface 1420 is, in some embodiments, a stand-alone server computer; in other embodiments, grid interface 1420 is a web page located on a host web server; in yet other embodiments, grid interface 1420 is a stand alone software application either distributed on disc to consumers or downloaded by consumers, and adapted to allow a master iNode 1410 or plurality of load and source iNodes to connect via network 1402 to itself in order to collect usage statistics which it then sends on via grid data network 1401 to operation center 1430. Grid data network 1401 is in some embodiments the Internet, while another embodiments it is a dedicated data network operated by utility. In some embodiments, load iNodes 321 and source iNodes 322 connect via data network 1400 directly to grid interface 1420, and no master iNode 1410 is present. In other embodiments, consumers participating in a smart grid fractional smart metering system such as that disclosed herein will have a variety of arrangements, some of them using a master iNode 1410 and plurality of child iNodes (such as load iNode 321 and source iNode 322), while others will have only source iNodes 321 and load iNodes 322, and yet others will have hybrid architectures in which Master iNode 1410 is present and aggregates statistics from a plurality of child iNodes, but there is a further plurality of iNodes that connect directly to grid interface 1420.

It will be appreciated that according to the invention, statistical information concerning energy usage and generation can be accumulated at statistics server 1430 without the use of smart meters. It will further be appreciated that an element of risk is introduced on behalf of the utility under this arrangement, since the utility does not directly own or control the iNodes that are the source of the aggregated statistics. This is quite different from the situation common in the art today, in which smart meters owned by the utility collect all usage statistics. In order to mitigate the risk, utilities may collect aggregate statistics for periods corresponding to the time period for which routine meter readings are available. This data is generally already collected by utilities, as it is the basis for their billing of ratepayers for actual energy usage (on a monthly or bimonthly basis usually). Usage data from traditional meter reading is obtained by statistics server 1430 from operations database 1440, which in many embodiments is a relational database containing financial and operational data pertaining to a utility, although other database formats and architectures may be used. The aggregate statistics obtained from iNodes via grid interface 1420 can then be compared to the usage data obtained operational database 1440 (again, this is the usage data collected from routine meter readings). Clearly the total from the iNodes should be less than or equal to the total amount obtained from the meter (which by definition is the total of all energy used by the particular ratepayer for the particular period measured using the meter), and furthermore the ratio of the total measured by iNodes divided by the total measured by a meter gives a good estimate of the proportion of the total energy load of the given premises that is monitored by iNodes. In one embodiment, this ratio is assumed to be more or less constant (although it can be recalibrated each time a meter reading is taken), and the total usage of energy for any given time interval can be taken to be the total measured by iNodes, divided by this ratio. Thus in this embodiment a utility is able to offer demand-based pricing to consumers without the necessity of installing smart meters. In effect, the aggregate of the iNodes for a particular ratepayer act as a “fractional smart meter”, providing interval-based measurement (and two-way communications between utility and ratepayer in real time) for a fraction of the loads (and sources) present at ratepayer's premises. In some cases, regulators or consumers may be unwilling to allow prices to be set based on a sampling approach such as that just outlined. In these cases, a fractional smart metering approach may still be used according to the invention, in which the loads measured by iNodes (and in the generation of energy if measured) are priced according to a demand-based pricing scheme (as if a smart meter were physically present, measuring their energy usage on a small time interval basis), while the balance of energy usage (as determined by subtracting the total iNode-measured energy usage from the meter-measured usage) is priced as usual using a fixed price tariff.

In fractional smart metering systems according to the invention, it is important to be able to guard against fraud. One possible source of fraud would be to disconnect iNodes from data network 1400 during periods of peak demand (and therefore the price), and enter reconnect the iNodes during other periods. This would allow a fraudulent consumer to pay a lower-than-average price for iNode measured energy during periods of low usage (and low-price), while still paying the averaged fixed price tariff rates for all energy used during peak periods. To avoid this, in some embodiments a heartbeat mechanism (such as are well-known in the art) may be used to detect the disconnection of any iNodes. This does not protect, however, against fraud such as by disconnecting electrical loads 331 from load iNodes 321, in order that the electrical loads 331 can be operated without being detected by load iNodes 321. A more robust solution is to tightly integrate loads 331 and load iNodes 321 (or sources 332 and source iNodes 322), such as by encouraging the adoption of energy-efficient appliances with integrated, network ready, iNodes. Since many of the largest electrical loads used by consumers are appliances with integrated electronic controls, such as heating, ventilation, and air conditioning systems, refrigerators, stoves and ranges, dishwashers, water heaters, hot times, and the like, and since there is already precedent for the promotion of energy-efficient appliances by utilities and regulators, it is envisioned that iNode equipped appliances will allow fractional smart metering according to the invention to be practical.

In an embodiment of the invention, once fractional smart metering is in place based on received aggregate data from a plurality of source and load iNodes for a plurality of consumers of energy, statistics server 1430 computes usage values for time increments and passes them to pricing system 1441 in order to enable pricing system 1441 to compute demand-based prices for each consumer. Pricing systems 1441 that are adapted to compute demand-based pricing are well-known in the art; what is new is providing fractional-smart-meter-based usage data in one of at least two forms, according to the invention. One form is simply the total of energy usage net of generation by all monitored energy resources associated with a given consumer (monitored in the sense that an associated iNode is present and feeds data as described above to statistics server 1430). According to this embodiment, when a monthly (or bimonthly) meter reading is obtained and passed to pricing system 1441, the sum of all interval readings from iNodes (which were already priced based on demand) is subtracted from the total, and the remaining balance is billed at the normal, fixed tariff rate for the applicable consumer. In a second form, the ratio method described above is used to compute the total usage for each time increment based on fractional-smart-meter-based measurements (that is, by dividing the total energy usage, net of generation, measured by iNodes by the fraction computed previously for the applicable consumer of total energy load that is monitored), and to price the entire usage using demand-based pricing. If this embodiment is used, then when regular meter readings are obtained, the total energy usage measured by the meter can be compared to the total computed by summing each time increment's value that was obtained by the second form, and comparing the two values. If there is a significant variance (for example, a variance that exceeds a configurable maximum tolerance) between the computed and measured total usage, then the ratio method's results would be suspect. The variance could have been caused by normal fluctuations in energy usage among monitored and non-monitored loads (the two types of loads may not behave identically over time, so that the ratio of monitored load to total load would in fact fluctuate), or by fraud. In one embodiment, when this situation is reached, the first form is then preferentially selected by pricing system 1441; in other embodiments, utilities or regulators may decide that, where error is known, the total usage for each time increment is adjusted to the lower of a pro-rated amount based on total usage according to the “real” meter and the computed amount (in other words, resolve errors in favor of the consumer), although many other approaches are possible according to the invention. For example, in another embodiment statistics server 1430 computes an average percentage of total load consumed during each time increment for a sample of smart meter-equipped consumers similarly situated to the consumer of interest, and applies this percentage to the actual total usage of the consumer of interest to compute a value for each time interval.

It should be evident that the monitoring of a substantial portion of loads of a large set of consumers, using iNodes and without the necessity of deploying smart meters, makes possible a wide variety of demand management and demand-based pricing schemes that are mutually beneficial to utilities and their consumers. Achieving this without the need for massive deployments of smart meters that do little for consumers is highly desirable.

All of the embodiments outlined in this disclosure are exemplary in nature and should not be construed as limitations of the invention except as claimed below.

What is claimed is:

1. A fractional smart metering system, comprising:
a processor coupled to a packet data network; and
a server software module executing on the processor and coupled to an operational database containing at least energy usage information pertaining to an energy consumer and obtained from meter readings at the consumer's premises;
wherein the server software module is adapted to receive information over the network from a plurality of client software modules associated with energy resources further associated with the energy consumer;
wherein the server software module computes a measure of energy usage for a specific time interval for the consumer, said measure being determined at least in part based on a comparison between the information received from the client software modules associated with the consumer and the corresponding usage information obtained from the operational database.

2. A method for measuring energy usage, comprising the steps of:
(a) receiving information via a packet data network from client software modules associated with energy load devices or energy generating devices associated with an energy consumer;
(b) receiving information from an operational database pertaining to energy usage by the energy consumer and obtained from meter readings at the consumer's premises; and
(c) computing a measure of energy usage for a specific time interval for the consumer, said measure being determined at least in part based on a comparison between the information received from the client software modules associated with the consumer and the corresponding usage information obtained from the operational database.
